(19) United States
(12) Patent Application Publication
(10) Pub. No.: US 2025/0101261 A1
(43) Pub. Date: Mar. 27, 2025

(54) CHEMICAL MECHANICAL PLANARIZATION SLURRY PROCESSING TECHNIQUES AND SYSTEMS AND METHODS FOR POLISHING SUBSTRATE USING THE SAME

(71) Applicant: ARACA, INC., Tucson, AR (US)

(72) Inventors: Jason A. KELEHER, Naperville, IL (US); Kiana A. CAHUE, Joliet, IL (US); Yasa SAMPURNO, Tucson, AZ (US); Fred C. REDEKER, Livermore, CA (US); Ara PHILIPOSSIAN, Tucson, AZ (US)

(21) Appl. No.: 18/832,677

(22) PCT Filed: Aug. 12, 2022
(86) PCT No.: PCT/US2022/040147

§ 371 Date: Jul. 24, 2024

Related U.S. Application Data
(63) Continuation of application No. PCT/US2022/015424, filed on Feb. 7, 2022.
(60) Provisional application No. 63/335,783, filed on Apr. 28, 2022.

(51) Int. Cl. C09G 1/02; H01L 21/306

(52) U.S. Cl. CPC C09G 1/02; H01L 21/30625

(57) ABSTRACT

A Chemical Mechanical Planarization (CMP) system, apparatus, and method comprising providing a source of CMP slurry; modifying the source of CMP slurry to form a modified CMP slurry by directing a source of at least one of mechanical or electromagnetic wave energy at the source of CMP slurry; applying a flow of the modified CMP slurry to a wafer polishing apparatus at which a substrate is positioned; and performing a polishing operation on the substrate.

### CROSS-REFERENCE TO RELATED APPLICATIONS

This application claims priority to U.S. provisional application 63/335,783 (filed Apr. 28, 2022) and is a continuation-in-part of International Patent application PCT/US22/15424 (filed Feb. 7, 2022) which claims priority to U.S. provisional application 63/149,733 (filed Feb. 16, 2021), U.S. provisional application 63/150,683 (filed Feb. 18, 2021), U.S. provisional application 63/165,444 (filed Mar. 24, 2021) U.S. provisional application 63/186,343 (filed May 10, 2021); U.S. provisional application 63/188,305 (filed May 13, 2021) and U.S. provisional application 63/211,083 (filed Jun. 16, 2021), the entireties of each of which is incorporated by reference herein.

This application is related to U.S. Pat. Nos. 8,197,306, 8,845,395, 9,296,088, Korean Pat. No. 10-1394745, Japan Pat. No. 5,574,597, and Taiwan Pat. No. I486,233, the entireties of each of which is incorporated by reference herein.

### FIELD OF THE INVENTION

The present disclosure relates generally to CMP (Chemical Mechanical Planarization) for a semiconductor manufacturing process. More particularly, the present disclosure relates to enhancements to slurry formulations, as well as equipment and processes for polishing substrates such as semiconductor wafers.

### BACKGROUND OF THE INVENTION

Chemical Mechanical Planarization (CMP) is part of a semiconductor manufacturing process that performs material removal and planarizes metal, polysilicon, and/or dielectric layers during integrated circuit (IC) fabrication on a substrate, e.g., wafer. CMP may perform a chemical reaction followed by a mechanical force by applying abrasive particles to remove the metal deposits or the like forming the layers.

A CMP process generally includes the use of a slurry dispense system including an apparatus that outputs a source of slurry to a polishing pad to apply a combination of chemicals and abrasive particles to a rotary substrate polisher on which a wafer is positioned. Without a proper system, slurry material types and characteristics and the manner in which the slurry is applied may lead to lower material removal rates, larger than needed slurry consumption, undesirable surface scratches or other defects on the wafer.

The discussion above is merely provided for general background information and is not intended to be used as an aid in determining the scope of the claimed subject matter.

### SUMMARY

In one aspect, the present inventive concept provides a Chemical Mechanical Planarization (CMP) method comprising providing a source of CMP slurry; modifying the source of CMP slurry to form a modified CMP slurry by directing a source of at least one of mechanical or electromagnetic wave energy at the source of CMP slurry; applying a flow of the modified CMP slurry to a wafer polishing apparatus at which a substrate is positioned; and performing a polishing operation on the substrate.

In a first embodiment, a chemical mechanical planarization (CMP) method is provided. The method comprising: mixing (1) an aqueous CMP slurry (2) a capsulizing agent that forms a supramolecular structure selected from a group consisting of a vesicle, a micelle, a polyelectrolyte and a liposome and (3) a material additive selected from a group consisting of a ligand, a ligand-metal complex and a non-metal reactive-oxygen species (ROS) catalyst, thereby forming a modified slurry; directing at least one of mechanical or electromagnetic wave energy at the modified slurry, thereby forming an activated modified slurry; and planarizing a substrate while the substrate is exposed to the activated modified slurry.

In a second embodiment, a chemical mechanical planarization (CMP) method is provided. The method comprising: mixing (1) an aqueous CMP slurry (2) a capsulizing agent that forms a supramolecular structure selected from a group consisting of a vesicle, a micelle, a polyelectrolyte and a liposome and (3) a material additive selected from a group consisting of a ligand, a ligand-metal complex and a non-metal reactive-oxygen species (ROS) catalyst, thereby forming a modified slurry, wherein the material additive has a water solubility of less than 20 grams per liter when measured at 22° C.; directing mechanical wave energy at the modified slurry, thereby forming an activated modified slurry; and planarizing a substrate while the substrate is exposed to the activated modified slurry.

This brief description of the invention is intended only to provide a brief overview of subject matter disclosed herein according to one or more illustrative embodiments, and does not serve as a guide to interpreting the claims or to define or limit the scope of the invention, which is defined only by the appended claims. This brief description is provided to introduce an illustrative selection of concepts in a simplified form that are further described below in the detailed description. This brief description is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

So that the manner in which the features of the invention can be understood, a detailed description of the invention may be had by reference to certain embodiments, some of which are illustrated in the accompanying drawings. It is to be noted, however, that the drawings illustrate only certain embodiments of this invention and are therefore not to be considered limiting of its scope, for the scope of the invention encompasses other equally effective embodiments. The drawings are not necessarily to scale, emphasis generally being placed upon illustrating the features of certain embodiments of the invention. In the drawings, like numerals are used to indicate like parts throughout the various views. Thus, for further understanding of the invention, reference can be made to the following detailed description, read in connection with the drawings in which:

FIG. 1 is a diagram illustrating elements of a CMP slurry processing system, in accordance with some embodiments.

FIG. 2A is a flow diagram of a CMP method, in accordance with some embodiments.

FIG. 2B is a flow diagram of a CMP method, in accordance with other embodiments.

FIG. 2C is a flow diagram of a CMP method, in accordance with other embodiments.

FIG. 2D is a flow diagram of a CMP method, in accordance with other embodiments.

FIG. 2E is a flow diagram of a CMP method, in accordance with other embodiments.

FIG. 3 is a schematic diagram of a CMP slurry processing system, in accordance with some embodiments.

FIG. 4 is a perspective view of a slurry processing system, in accordance with some embodiments.

FIG. 4A is a top view of the slurry processing system of FIG. 4.

FIG. 4B is a top view of the slurry processing system of FIG. 4 with the cover seal system removed from the container housing to illustrate an interior of the container housing.

FIG. 5 is a cross-sectional front view of the slurry processing system of FIG. 4.

FIG. 6 is an exploded view of the slurry processing system of FIGS. 4 and 5.

FIG. 6A is as closeup cross-sectional front view of a sealed region of the slurry processing system of FIGS. 4-6.

FIG. 7 is bar graph illustrating comparative material removal rates from different CMP processes including the use of a slurry.

FIG. 8 is a diagram illustrating an operation of a slurry injection system in combination with a slurry processing system, in accordance with some embodiments.

FIG. 9A is a flow diagram illustrating an operation of a light generation system of a slurry processing system, in accordance with some embodiments.

FIG. 9B is a flow diagram illustrating an operation of a light generation system of a slurry processing system, in accordance with other embodiments.

FIG. 9C is a flow diagram illustrating an operation of a slurry processing system, in accordance with other embodiments.

FIG. 10 is a flow diagram depicting one method for planarizing a substrate.

FIG. 11 is a graph showing material removal rates at various test conditions.

FIG. 12 is a graph illustrating changes in material removal rates as a function of water solubility of a ROS additive.

FIG. 13A and FIG. 13B depict chemical structures of various capsulizing agents that can form micelles.

FIG. 14 depicts chemical structures of various capsulizing agents that can form vesicles.

FIG. 15 depicts chemical structures of various capsulizing agents that are polyelectrolytes.

FIG. 16 depicts chemical structures of various capsulizing agents that can form liposomes.

FIG. 17 depicts chemical structures of various material additives that form additional ROS under the disclosed conditions.

### DETAILED DESCRIPTION OF THE INVENTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

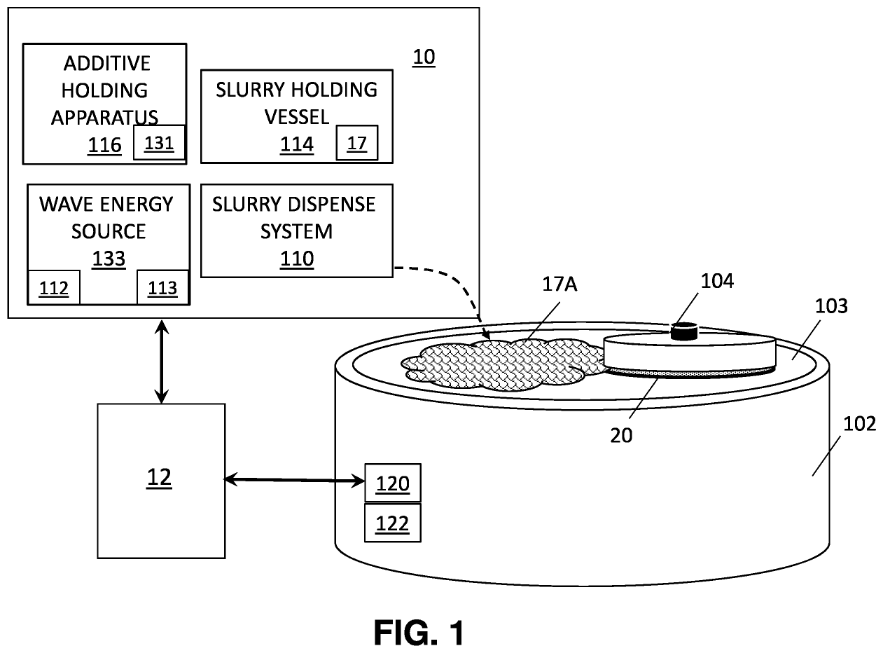

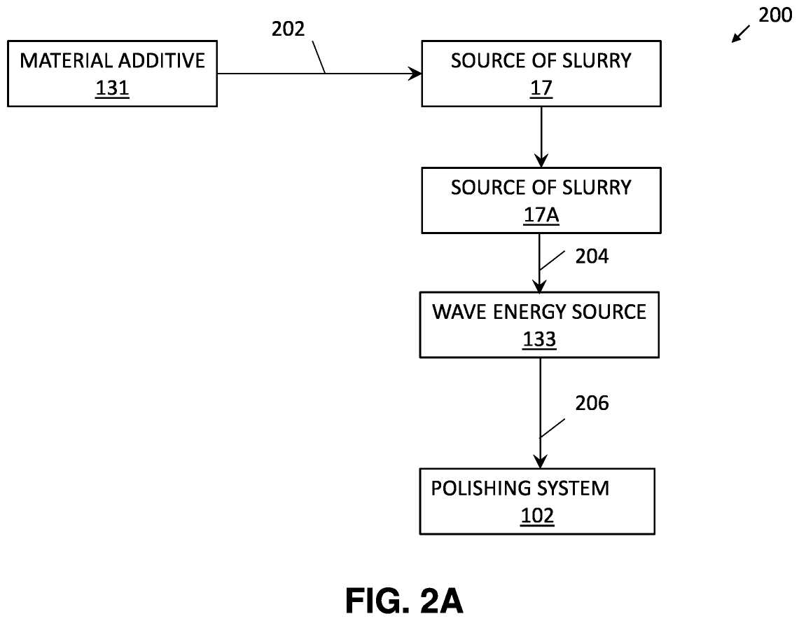

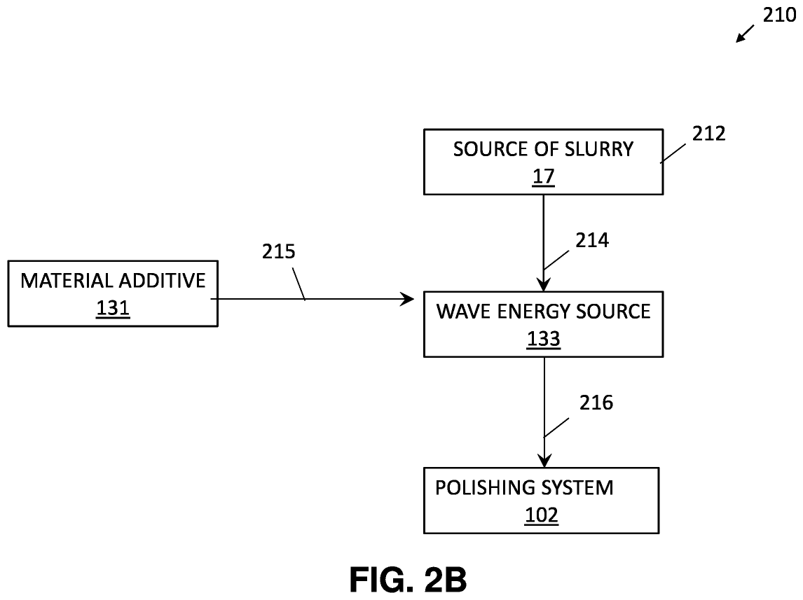

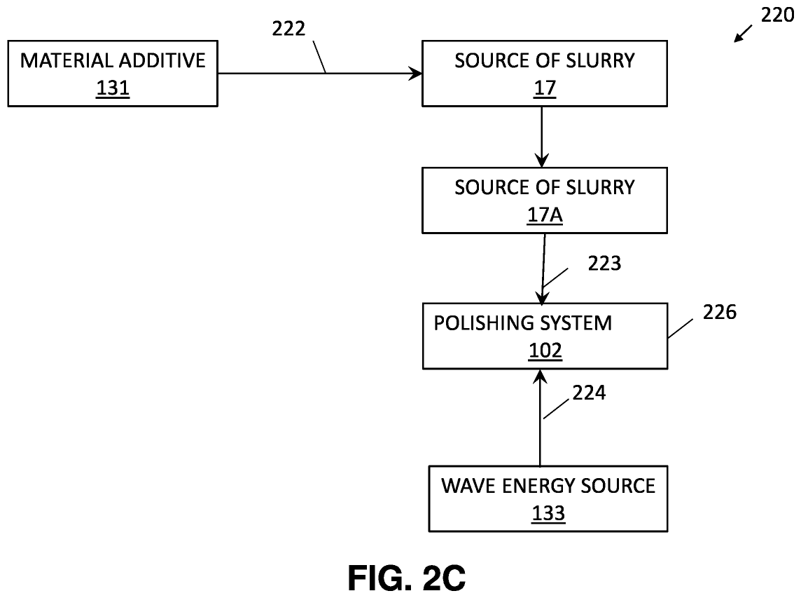

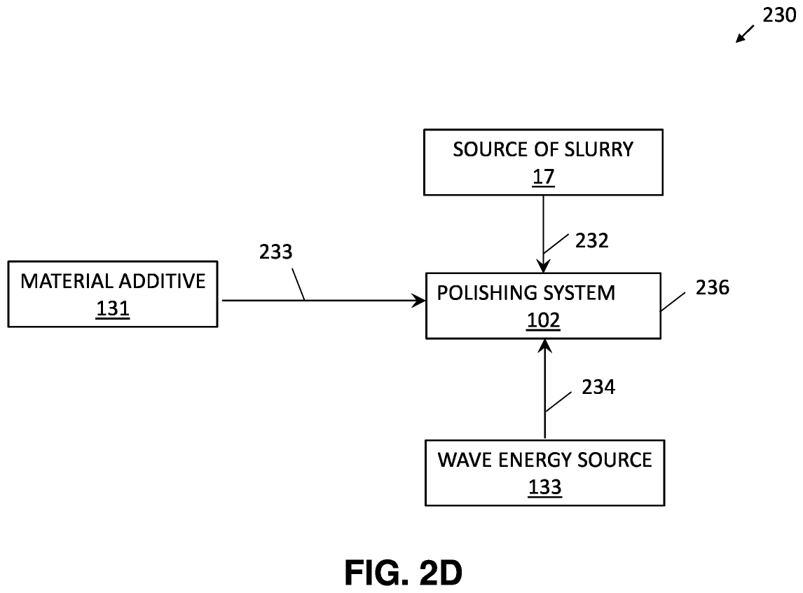

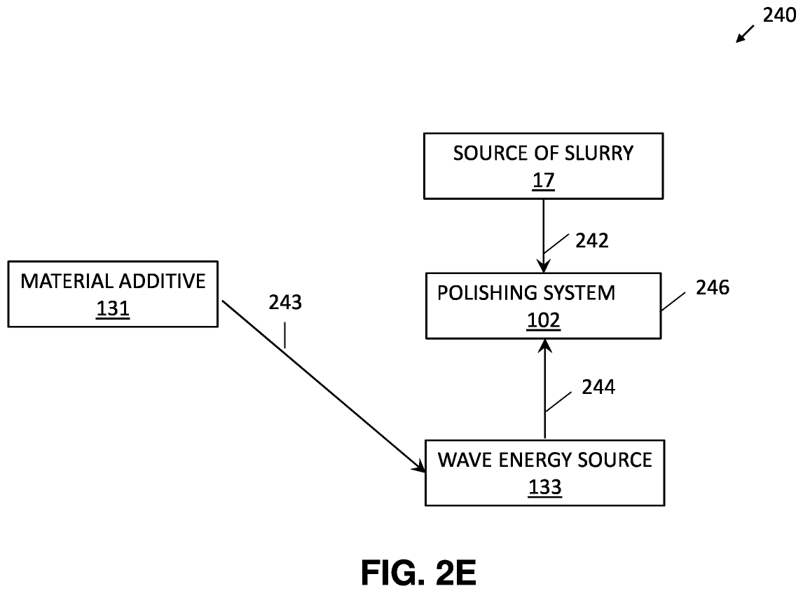

FIG. 1 is a block diagram of a slurry processing system 10 for a CMP process, in accordance with some embodiments. The slurry processing system 10 is constructed and arranged to provide a source of slurry, either an original source of slurry 17 (shown in FIG. 2A) stored in the slurry holding vessel 114 or a modified slurry 17A (shown in FIG. 1) that is enhanced or modified by one or more material additives 131, simply referred to as additives, for example, chemical additives. In some embodiments, the modified slurry 17A is alternatively or additionally enhanced or modified by a source mechanical and/or electromagnetic energy, for example, after output from the slurry holding vessel 114 and receipt by the slurry dispense system 110, to a wafer polishing system 102 including a polishing head 104 that rotates a substrate 20 (e.g. a wafer) on a polishing pad 103 of the system 102. The polishing pad 103 may be a concentrically grooved or XY-grooved polyurethane-based pad or have another pad configuration or material of construction. The CMP wafer or substrate polishing system 102 may include other well-known components such as motors such as servo motors and/or inverter motors, electronics, actuators, wafer carriers, robotics and wafer handling components, temperature sensors, retaining rings, shear and normal force transducers, IR detectors, and so on, but are not shown for brevity. In some embodiments, the wafer carrier provides an average pressure in the range of 0.6-8 PSI, and rotates from 15-200 RPM, but not limited thereto. The top layer of the substrate 20 for polishing can be formed of one or more materials such as copper, tungsten, aluminum, polysilicon, silicon dioxide, carbon-doped silicon dioxide, black-diamond, silicon nitride, tantalum, tantalum nitride, titanium, titanium nitride, cobalt, gallium nitride, ruthenium, silicon carbide, or a combination or alloy thereof used for shallow trench isolation (STI) CMP applications requiring the use of a slurry, for example, which can chemically react with the material(s) forming the substrate 20. In some embodiments the substrate 20 has a wafer size of 200 mm or 300 mm, but not limited thereto. The source of original slurry 17 or modified slurry 17A is delivered by a slurry dispense system 110 to the polishing pad 103. As described above, the slurry 17 shown on the polishing pad 103 can be an off-the-shelf or unadulterated source of slurry 17, or in other embodiments may be modified by a material additive 131, referred to as modified slurry 17A.

In some embodiments, the slurry dispense system 110 includes one or more slurry holding vessels 114, one or more additive holding apparatuses 116, a wave energy source 133.

The slurry holding vessel(s) 114 and/or additive holding apparatus(es) 116 can be storage tanks and other chemical additive delivery mechanisms, baffles, level sensors, chemical sensors, pumps, agitators, filters, on-board computers and controllers, flow meters, and so on. In some embodiments, the slurry holding vessels 114 can be 20-liter tanks including mixers, pumps, and sensors described herein. These elements of the slurry dispense system 110 can control the quality of a source of slurry 17, for example, by agitating, blending, filtering, circulating, or otherwise dispensing the slurry 17. In some embodiments, the slurry dispense system 110 offers a flow rate ranging from 10-500 cc/min, but not limited thereto, is illustrated by embodiments herein.

In some embodiments, the wave energy source 133 includes a sonic wave generation mechanism having one or more transducers or the like (not shown) that generate mechanical waves, e.g., sound waves, cavitation, vibrations, and the like, to acoustically activate the slurry liquids in a storage area of the slurry dispense system 110. In some embodiments, the sonic wave generation mechanism can direct acoustic energy in the megasonic, ultrasonic, or related acoustic frequency spectrum. The application of slurry to a substrate surface permits the passivation layer (which is being polished continuously) atop the substrate surface to be become softer and less dense by the chemical reaction with the slurry, which can be enhanced by the sonication of the slurry. In doing so, the material removal rates (RR) and/or other removal features with respect to films made of copper, tungsten, polysilicon, aluminum, silicon dioxide, carbon-doped silicon dioxide, black-diamond, silicon nitride, tantalum, tantalum nitride, titanium, titanium nitride, cobalt, gallium nitride, ruthenium, silicon carbide, or a combination or alloy thereof in response to the sonication energy applied to the slurry during the sonication process before dispensing the slurry on the pad 103 are higher as compared to no sonication. Furthermore, the aforementioned softened passivation layer formed by the electromagnetic wave activated chemical reaction with the sonicated slurry, can result in lower wafer-level defects and better polished surface quality when it comes to films made of copper, tungsten, polysilicon, silicon dioxide, aluminum, carbon-doped silicon dioxide, black-diamond, silicon nitride, tantalum, tantalum nitride, titanium, titanium nitride, cobalt, gallium nitride, ruthenium, silicon carbide, or a combination or alloy thereof. A higher material removal rate is preferred because removal rate is inversely proportional to polish time. As such, the productivity of the CMP module in the integrated circuit manufacturing factory increases since wafer throughput goes up when the production time is shorter. Also, the resulting shorter polish time means that less slurry is needed for polishing a wafer through the CMP process. This results in a cost advantage as slurries are the most expensive consumables in the CMP module. Furthermore, it is a right step towards environmentally conscious manufacturing since slurry may be dangerous for the environment and is also expensive to treat and legally discard. Moreover, attaining lower wafer-level defects are preferred because excessive levels of defects reduce product yield. As such, any reduction in defect levels, and the quality of the surface finish of the material being polished, are productivity boosters.

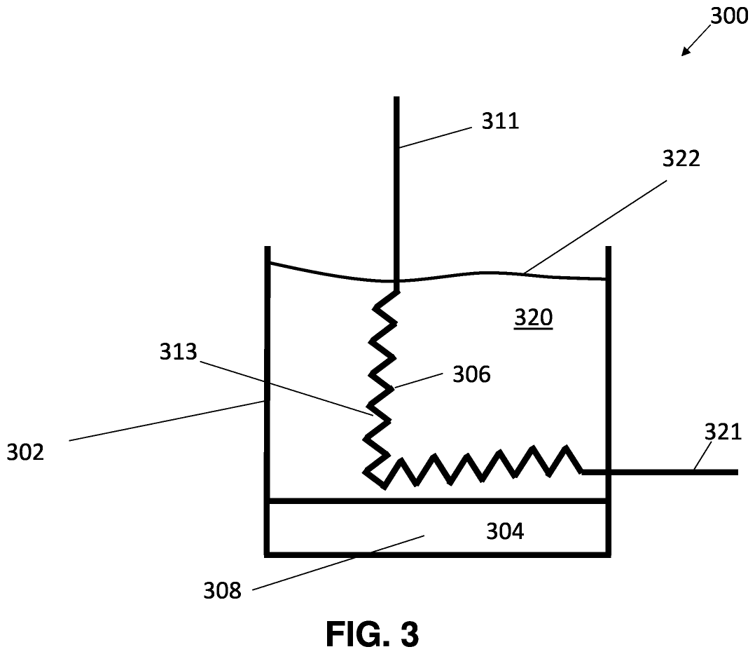

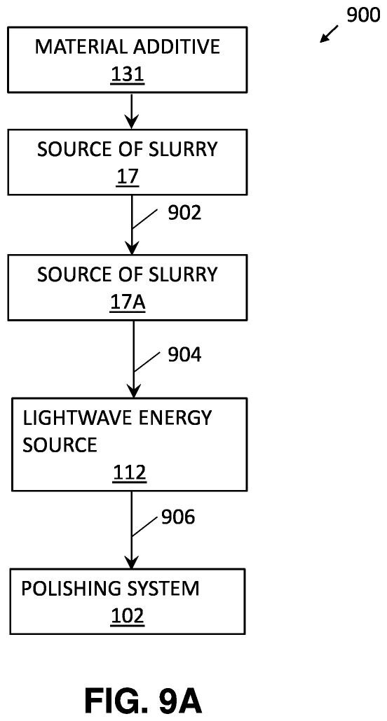

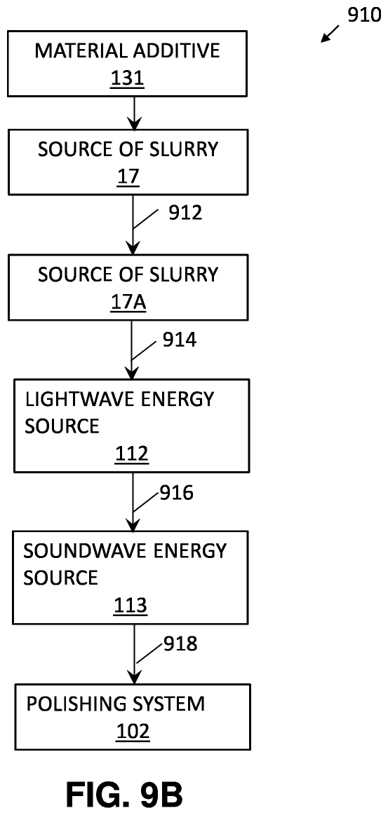

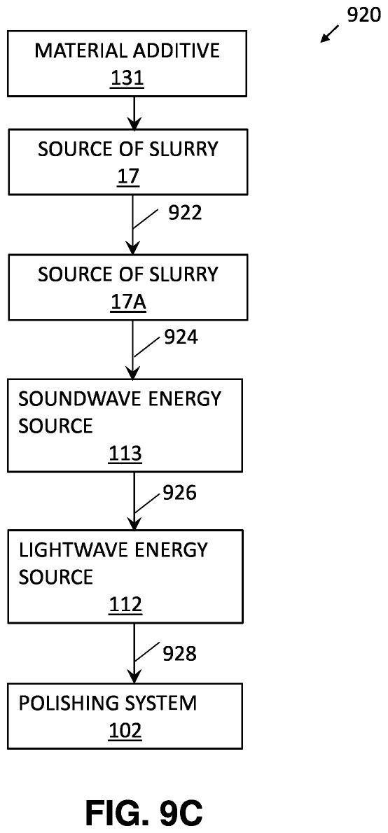

In some embodiments, the wave energy source 133 of the CMP slurry processing system 10 includes a source of electromagnetic waves, e.g., a lightwave energy source, for example, shown in FIGS. 9A-9C, that is constructed and arranged to irradiate the source of slurry 17. In some embodiments, the modified slurry 17A includes a material additive to induce ligand-to-metal-charge-transfer (LMCT) upon irradiation by the lightwave energy source 112 of the wave energy source 133 (see FIGS. 9A-9C) to generate the photo-active slurries for a CMP operation. For example, by modulating the wavelength or the strength of electromagnetic radiation by the lightwave energy source 112, one can modulate removal rate and other process performance parameters at the wafer-level. The wavelengths of the light may range from, but not be limited to, 200 to 800 nm. In some embodiments, a lightwave energy source of the wave energy source 133 (shown in FIG. 1) is proximal to the polishing pad 103 for irradiating the slurry prior to dispensing atop the polishing pad 103. In these same embodiments, an acoustic source of the wave energy source 133 (not shown in FIG. 1) is integral or otherwise part of the slurry dispense system, for example, shown in FIGS. 3-6.

The slurry processing system 10 may include a data analysis and reporting computer 12 that communicates with the wafer polishing system 102 and slurry dispense system 110 via a special purpose processor 120. The processor 120 can communicate with a controller 122 to manage and control the polisher and injector operations.

FIG. 2A is a flow diagram of a CMP method, in accordance with some embodiments. In some embodiments, the method 200 may include some or all elements of a CMP slurry processing system 10 of FIG. 1.

The method 200 can commence with step 202, where a source of slurry 17 is modified to form a modified slurry 17A that includes one or more material additives 131, for example, a chemical additive. In other embodiments, the slurry is unmodified, for example, an off-the-shelf or other commercially available slurry 17. The material additives 131 can be selected based on their functionality, for example, described in examples below. In other embodiments, other slurry additives can modify the liquid surface tension and the contact angle with the substrate, for example, described in examples below.

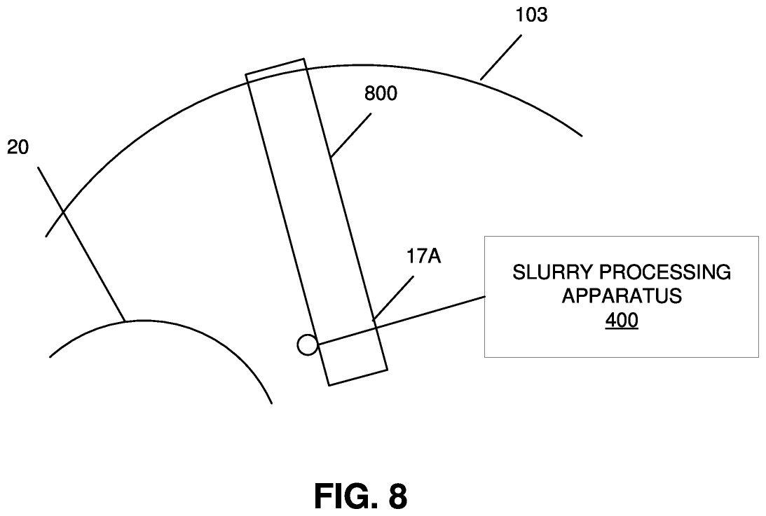

At step 204, a source of mechanical, e.g., sonic, and/or electromagnetic, e.g., lightwave energy is applied to the modified slurry 17A. In some embodiments, the method 200 does not include step 202. and proceeds directly to step 204 where the off-the-shelf or unmodified slurry 17 does not include additives 131. In some embodiments, the slurry may flow through a mega-sonication and/or light enhancing process performed by the wave energy source 133 before dispensing at step 206 on the polishing pad 103 as part of a CMP process or the like. In some embodiments, a photo-active rate enhancement material is added to the slurry which, when excited with a lightwave energy source of the wave energy source 133, can increase material removal rate. In some embodiments, additives in addition to or instead of the material additives of step 202 are applied including a photo-active composite vehicle. In some embodiments, the wave energy source 133 may operate with a slurry injection system, for example, shown in FIG. 8, and/or described in one or more of U.S. Pat. Nos. 8,197,306, 8,845,395, 9,296,088, Korean Pat. No. 1,394,745, Japan Pat. No. 5,574,597, and Taiwan Pat. No. I486,233, the entireties of each of which is incorporated above.

FIG. 2B is a flow diagram of a CMP method 210 in accordance with other embodiments. At step 212, where a source of slurry 17 is unmodified prior to a receipt (step 214) by a wave energy source 133 which applies a source of mechanical, e.g., sonic, and/or electromagnetic, e.g., light, wave energy to the unmodified slurry 17.

At step 215, the source of slurry at the wave energy source 133 is further modified by one or more chemical additives 131, which is provided to the wave energy source independently of the off-the-shelf or commercially available slurry. In this embodiment, the wave energy source 133 includes devices for applying or electromagnetic, e.g., light, wave energy as well as a holding device or region for receiving, temporality holding, and applying the material additive(s) 131 to the slurry in the wave energy source 133. In some embodiments, step 214 is performed prior to step 215. In other embodiments, steps 214 and 215 are performed concurrently. In other embodiments, step 214 is performed after step 215.

At step 216, a polishing operation is performed with the slurry modified by both the material additive(s) 131 and the wave energy source 133.

FIG. 2C is a flow diagram of a CMP method 220 in accordance with other embodiments. Step 222 may be similar to step 202 of FIG. 2A, where a source of slurry 17 is modified to include one or more material additives 131. At step 223, the modified slurry 17A is output to a polishing system 102.

At step 224, a mega-sonication and/or light enhancing process is directed at a polishing pad 103 of the polishing system 102 on which the modified slurry 17A of step 223 is provided.

At step 226, a polishing operation is performed on the slurry modified by both the material additive of step 222 and the mega-sonication and/or light enhancing process of step 224.

FIG. 2D is a flow diagram of a CMP method 230 in accordance with other embodiments. The unmodified slurry 17 and material additive 131 are independently output (steps 232 and 233, respectively) to the polishing system 102. At step 234, the mega-sonication and/or light enhancing process is directed at the polishing pad 103 on which the slurry 17 of step 232 and material additive 131 of step 233 are independently provided.

At step 236, a polishing operation is performed on the slurry 17 modified by the material additive 131 of step 233 and the wave energy source 133 applying a mega-sonication and/or light enhancing process of step 234 independently directed at the polishing system 102.

FIG. 2E is a flow diagram of a CMP method 240 in accordance with other embodiments. At step 242, a source of off-the-shelf or commercially available slurry 17 is output to the polishing system 102. At step 243, a material additive 131 is output to the wave energy source 133, which applies mechanical and/or electromagnetic wave energy to the material additive 131. At step 244, the mega-sonication and/or light enhancing process outputs the modified additive 131 to the polishing pad 103 on which the slurry 17 of step 242 is independently provided.

At step 246, a polishing operation is performed on the previously unmodified slurry 17 that forms the modified slurry 17A at the polishing system 102 in response to a receipt and processing of the additive 131 modified by the wave energy source 133 at step 244.

FIG. 3 is a schematic diagram of a CMP slurry processing system 300, in accordance with some embodiments. The slurry processing system 300 may be part of the dispense system 110 of FIG. 1. The slurry processing system 300 is constructed and arranged to activate, agitate, blend, filter, circulate, and/or dispense a source of slurry to a substrate surface. Some of these well-known slurry dispense features are not described in detail for brevity. Other features are described in additional detail because they include applications, modifications, and variations that fall within the true scope of the present inventive concept.

In some embodiments, the CMP slurry processing system 300 comprises a storage container housing 302, a sonic agitation device 304, a tubing 306 having a non-coiled inlet region 311, a non-coiled outlet region 321, and a coiled section 313 between the non-coiled inlet region 311 and the non-coiled outlet region 321, and a power generator 308.

The container housing 302 is constructed and arranged as an open-top bowl or the like to receive and hold a source of deionized water 320 which is positioned about the tubing 306. In some embodiments, the top of the housing 302 is sealed and includes an inlet for receiving the deionized water 320. The deionized water 320 can fill the container housing 302 to a level 322 so that the coiled section 313 of the tubing 306 is immersed in water and the non-coiled inlet region 311 extends from and is separate from the container housing 302 holding the deionized water 320. The tubing 306 can receive a source of liquid such as slurry that flows from an inlet of the non-coiled inlet region 311 to an outlet of the non-coiled outlet region 321 for dispensing onto a CMP polishing apparatus. As the slurry liquid passes through the coiled section 313 of the tubing 306 immersed in the water, a power generator 308 activates the sonic agitation device 304 to sonically agitate or excite the water with sufficient energy to extend the sonic waves through the plastic surface of the tubing 306 to the slurry liquid as the slurry flows through the coiled section 313 to the non-coiled outlet region 321 of the tubing 306, then to the pad on a platen of the CMP polishing apparatus, for example, shown in FIG. 1. In some embodiments, the sonic agitation device 304 includes one or more sonic transducers. In some embodiments, the power generator 308 is an integrated RF power generator.

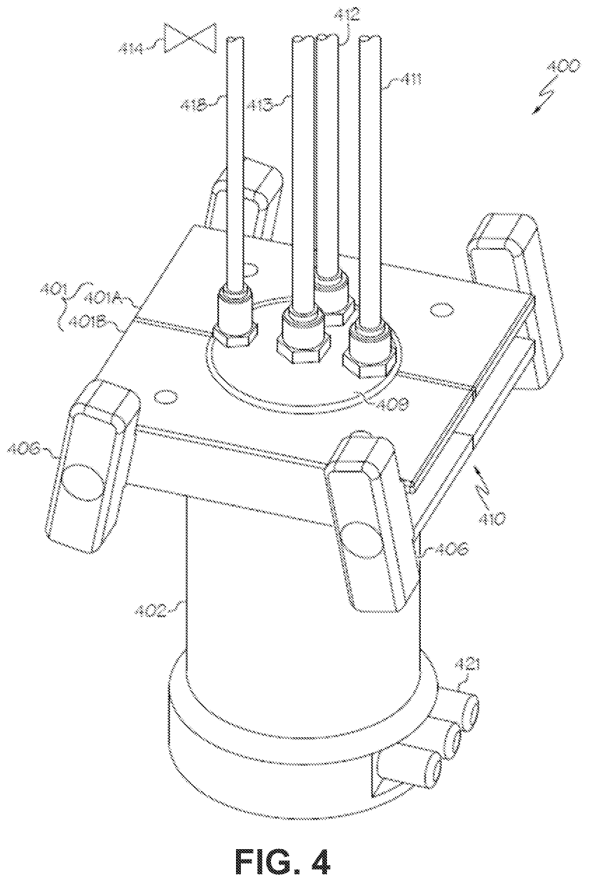

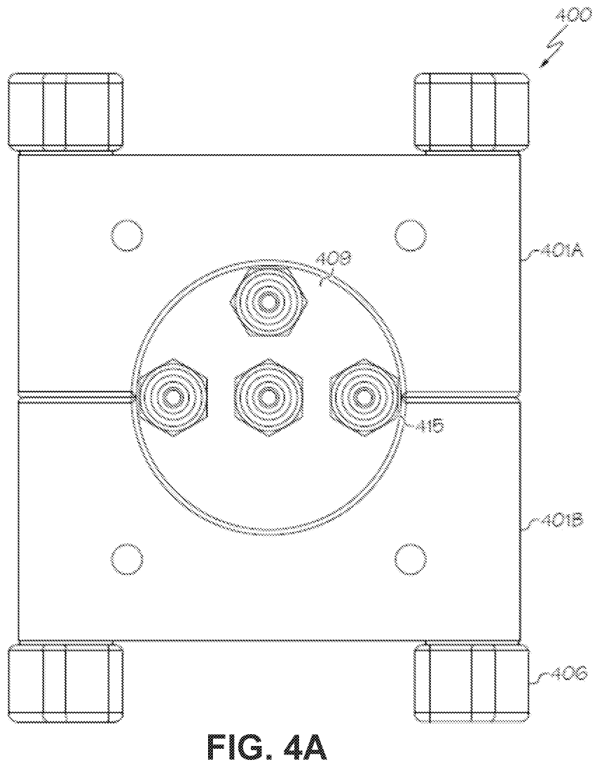

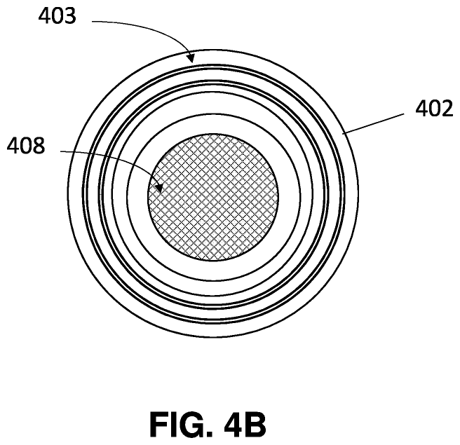

FIGS. 4-6A illustrate a slurry processing apparatus 400, in accordance with some embodiments. The slurry processing apparatus 400 may be part of or entirely comprised of the slurry processing system 10 of FIG. 1. However, the slurry processing system 10 of FIG. 1 is not limited to the slurry processing apparatus 400. For example, the slurry processing system 300 of FIG. 3 may be incorporated as part of the slurry processing system 10 of FIG. 1. A difference between the slurry processing apparatus 400 and the CMP slurry processing system 300 of FIG. 3 is that the slurry processing apparatus 400 of FIGS. 4-6 is encapsulated and leak-proof to permit the apparatus 400 to provide a continuous and direct flow of any type of CMP slurry. In addition, the slurry processing apparatus 400 can process slurry in the absence of a coiled tubing. The slurry processing apparatus 400 is constructed and arranged to reduce inefficiencies that may occur with CMP slurry sonication for a polishing operation, in which the slurry may receive 5% or less of the acoustic energy.

In some embodiments, the slurry processing apparatus 400 includes a container housing 402, a cover seal system 410, and a set of inlets, outlets, and connectors 411-413, 418, and 421.

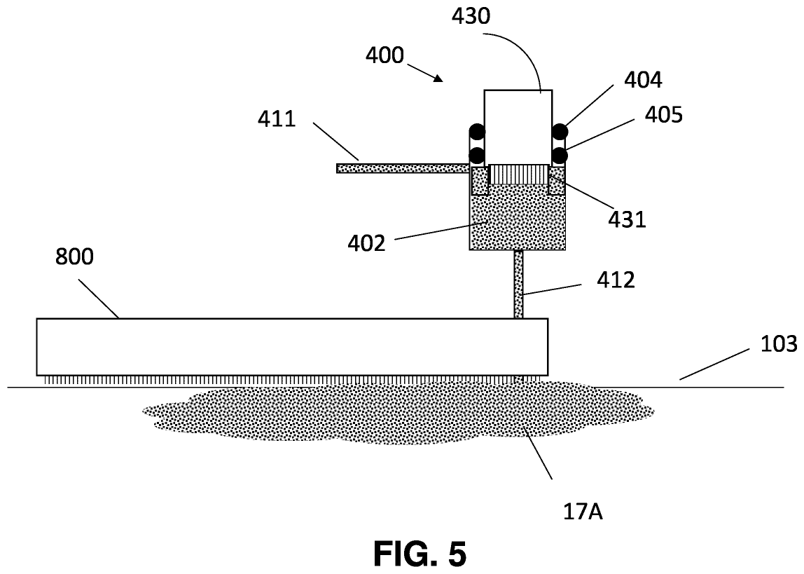

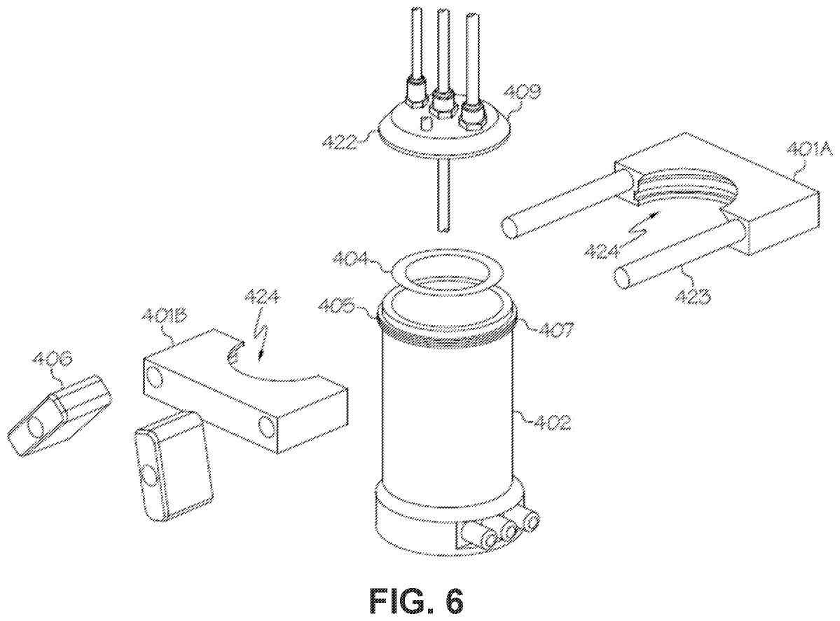

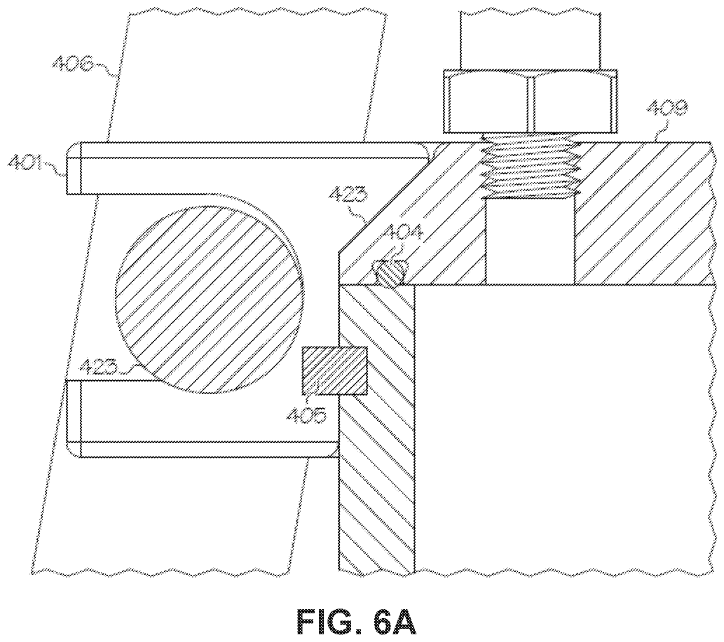

The container housing 402 is constructed and arranged to be encapsulated and sealed by the cover scal system 410 (shown in detail in FIG. 6A). The container housing 402 can receive and hold a source of slurry and is further constructed and arranged for permitting a continuous flow of slurry from an outlet 412. As shown in FIG. 4B. an opening 403 exposes an interior 408 of the housing 402. In some embodiments, the interior 408 is formed of Teflon™ or the like. The interior 408 may include an active area in the interior 408 at which an acoustic resonator or other acoustic energy producing device 431 enclosed in a transducer housing 430 (see FIG. 5), that may provide acoustic energy to a source of slurry, either modified slurry 17A modified by a chemical additive, or unmodified slurry 17 sealed in the container housing 402. In some embodiments, the acoustic energy producing device may be a lightwave energy source, e.g., like or the same as a lightwave energy source, which may be external to the container housing 402 and directs light at the source of slurry flowing from the outlet tube 412, or which may at the interior 408 of the container housing 402. In some embodiments, the lightwave energy source is separate from the acoustic energy producing device of the container housing 402. In some embodiments, the acoustic energy producing device may be part of, similar to, or the same as the wave energy source 133 of FIGS. 1-2E or sonic agitation device 304 of FIG. 3 so details thereof are omitted for brevity. A power supply (not shown in FIGS. 4-6, but may be similar to power generator 308 of FIG. 3) may power the acoustic energy producing device. The power supply may be similar to or the same as the power generator 308 of FIG. 3 so details thereof are omitted for brevity. In some embodiments, the acoustic energy producing device applies a piezoelectric effect that produces acoustic waves and cavitation that agitate the slurry, which in turn is output to the polishing pad on top of a platen of the polishing system 102 (see FIG. 1) where it polishes the surface of the substrate 20 by removing by forming a chemical passivation layer on the surface of the substrate which is then abraded mechanically by the pad and carried away by the slurry.

As shown in FIGS. 4, 6 and 6A, the cover seal system 410 is constructed for forming a fluid-tight seal over the opening 403 of the container housing 402. The container housing 402 can be constructed, for example, machined, to comply with or match the clamp portions 401A, 401B and cover element 409 to maintain a sealing compression interface between the cover seal system 410 and the container housing 402. In some embodiments, the cover seal system 410 includes a slip fit element 401, a recessed captive o-ring 404, a shear ring 405, and a cover element 409. Details of the cover seal system 410 are described below.

In some embodiments, the slurry processing apparatus 400 includes an inlet tube 411, an outlet tube 412, a vent tube 413 (also referred to as lines, respectively), and a gas inlet tube 418 that are mounted on, and extend through, a circular disc such as the o-ring 404. In some embodiments, the outlet tube 412 has a length that is greater than a length of the inlet tube 411 and vent tube 413 so that, unlike the inlet tube 411 and vent tube 413, a portion of the outlet tube 412 extends through at least a portion of the interior of the container housing 402 to be submerged in the slurry in the container housing. The inlet tube 411 and vent tube 413 may extend from holes in the o-ring 404 in a direction away from the container housing 402. In some embodiments, the three tubes 411-413 are pressure-fitted and have heights that can be individually adjusted by loosening the nuts 415 (see FIG. 4A) holding the tubes in place. When the nuts 415 are loosened, the tubes can move freely up or down to a desired height from the surface of the cover element 409. The nuts can then be tightened to secure the tubes against the cover element 409, moving the tubes up or down to the desired height and then tightening the nuts so that the tubes are held securely. The tubes 411-413, and 418 can be pressure fitted and replaceable.

The inlet tube 411 provides a slurry inlet to the closed system. The vent tube 413 provides a vent line 30 to allow trapped air to escape the housing 402 during an initial priming operation where the container receives and is some or partially filled with slurry prior to a valve 414 atop the vent tube 413 is closed and allows the housing 402 to receive a continuous slurry flow from the inlet 411 via the cover seal system 410 providing a fluid-tight seal at the opening 403.

The gas inlet tube 418 is configured to inject or percolate gases into the container housing 402 such as ozone or oxygen.

In some embodiments, the connectors 421 at the bottom of the housing 402 shown in FIG. 4 may include a purge gas return, RF cable inlet, and temperature sensor cable, respectively, but are not limited thereto.

Returning to FIGS. 6 and 6A, in some embodiments, the container housing 402 has a groove 407 that is machined or otherwise formed about a periphery of the housing 402 proximal the container opening 403 for receiving and fitting in place the shear ring 405 so that the shear ring 405 can provide a fluid-tight seal about the container housing 402 when the cover element 409 is removably attached about the container opening 403. The shear ring may, for example, be made of DELRIN®.

The o-ring 404 can be formed of a material that permits the retaining o-ring 404 to provide a fluid-tight seal such as rubber, plastic, or the like. In particular, the o-ring 404 seals the top region of the container housing 402 like or the same as the inside diameter of the interior 408 of the container housing 402 limited only by the tolerances of the container housing 402. In some embodiments, the top sealing surface and the groove underneath the cover element 409 in which the o-ring 404 is positioned can be machined for a smooth finish. When the o-ring 404 is installed, it maintains a sealing compression interface between the cover seal system 410 and the container housing 402. In some embodiments, the o-ring 404 is formed of Solid Virgin TEFLON™. In some embodiments, the o-ring 404 is formed of a fluoroelastomer material such as VITON™ to form a FEP encapsulated VITON™ o-ring that provides sufficient compression with a high degree of chemical resistance.

The cover element 409, also referred to as a lid, may be disc-shaped and have a peripheral region 422 that is threaded. The slip fit element 401, also referred to as a clamp, includes a first clamp portion 401A and a second clamp portion 401B that are constructed and arranged to couple to each other. In doing so, the first clamp portion 401A includes two rods 423, also referred to as threaded rods, that extend from the body of the first clamp portion 401A. In some embodiments, the body has a hemispheric interior 424. The rods 423 can be inserted into holes of the second clamp portion 401B (see FIG. 6A), which likewise has a hemispheric interior 424. When coupled together, the first and second clamp portions 401A. 401B collectively have a central hole formed by the hemispheric interiors 424, which is likewise threaded to mate with the peripheral region 422 of the cover element 409. Also, the rods 423 prevent torque or other rotational forces from occurring that may cause the clamp portions 401A. 401B to separate from each other, or to otherwise affect a seal formed between the cover seal system 410 and the container housing 402. The hemispheric interior 424 includes a threaded collar to surround and form a threaded relationship with the threaded peripheral region 422. In some embodiments, the peripheral region 422 is constructed and arranged to taper or has an angle relative to the threaded interior of the hemispheric interior 424, for example, as shown. For example, the angle may be 45 degrees from the vertical axis so that the bottom surface of the disc has a width, circumference, diameter, or related dimension that is greater than that of the top surface. The rods 423, or pins or the like, may be threaded to form a threaded relationship with the wingnuts 406, which when rotated, can tighten the first and second clamp portions 401A, 401B with respect to each other. The wingnuts 406 are designed to be hand-tightened for easy removal and assembly and to allow for handling with gloves regardless of the size of the user's hands. The wingnuts 406 terminate at the clamps formed by the first and second clamp portions 401A, 401B of the slip fit element 401 at exactly the correct distance for compression of the o-ring 404 and/or shear ring 405. The threaded collar of the slip fit element 401, the rods 423 and wingnuts 406 can collectively form a string scal that surround the cover element 409 and form a string seal at the cover seal system 410. The cover scal system 410 in turn, in particular, the o-ring 404, forms a seal with the shear ring 405 and container housing groove 407. In some embodiments, the o-ring 404 and shear ring 405 form a “clamshell” arrangement with respect to sealing the opening 403 of the container housing 402. Another feature is that the slurry processing apparatus 400 can be operated by a single person. The clamp portions 401A, 401B can be interchangeable and can be added or removed one at a time from the container housing 402, since each can independently rest on, or otherwise apply a force to the o-ring 404. The wingnuts 406 and rods 423 can be interchangeable and removed one at a time as each can independently rest in a groove of the clamp portion 401A, 401B, respectively.

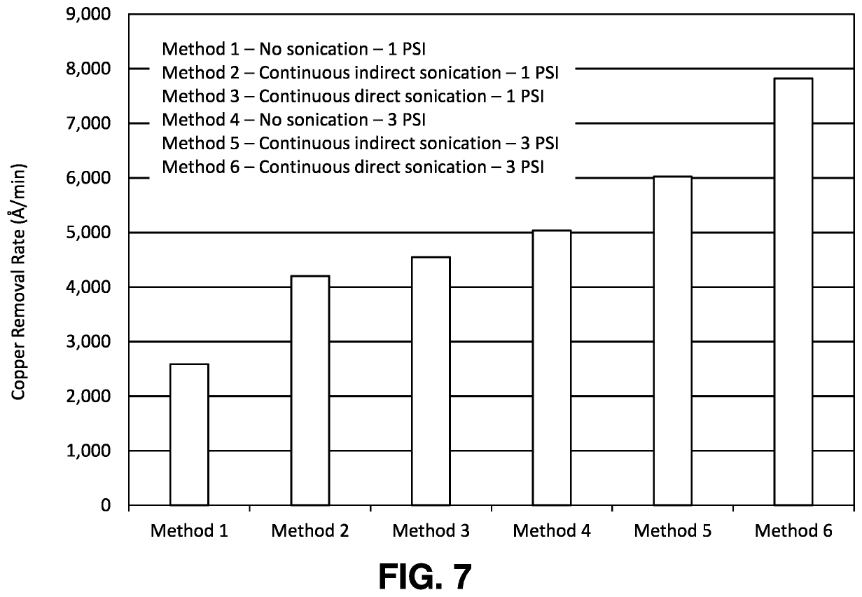

During a CMP polishing process, a slurry liquid is injected into the interior 408 of the housing 402 through the inlet 411 and exits the housing 402 through the outlet 412. Polishing results obtained using various methods are shown in FIG. 7. In particular, the removal rate results from a copper CMP operation using bulk copper slurry or the like is obtained where no sonication is performed (Methods 1 and 4), tube sonication (shown in FIG. 3—Methods 2 and 5) and continuous flow sonication (shown in FIGS. 4-6—Methods 3 and 6). Shown is a significant increase in a material removal rate by Methods 3 and 6 performed by the slurry processing apparatus 400 of FIGS. 4-6. More specifically. the bar graph in FIG. 7 shows a higher copper removal rate at a working wafer pressure of 1 PSI as removal rates increase. At 3 PSI, additional favorable copper removal rate results are achieved using the slurry processing apparatus 400.

FIG. 8 is a diagram illustrating an operation of a slurry injection system 800 in combination with a slurry processing apparatus 400, in accordance with some embodiments. Although the slurry processing apparatus 400 of FIGS. 4-6 is described, the slurry processing system 10 of FIG. 1 can equally apply. For example, the slurry injection system 800 can be part of the slurry processing system 10 along with the slurry processing apparatus 400.

The slurry injection system 800 is constructed and arranged for coupling with a rotary substrate polisher on which a substrate 20 is positioned, for example, wafer polishing system 102 of FIG. 1. During a polishing operation, the slurry injection system 800 is positioned relative to the substrate 20 rotating on the pad 103 of the polishing apparatus so that a source of modified slurry 17A is output along a track including holes at the bottom portion of the injection apparatus.

In some embodiments, the slurry is modified by the wave energy source 133 and output from the wave energy source 133 to the slurry injection system 800. The slurry injection system 800 in turn can output the slurry to the polishing pad 103 via the holes and/or track.

FIGS. 9A-9C illustrate various applications of a lightwave energy source 112 of a wave energy source 133 of a CMP slurry processing system, in accordance with some embodiments. The lightwave energy source 112 may include a pump or the like that can output a source of slurry to one or more light emitting elements after which the slurry modified by the light energy emitted by the light emitting elements can be output from the lightwave energy source 112.

The method 900 shown in FIG. 9A can commence with step 902, where a source of slurry 17 is modified to form a modified slurry 17A that includes one or more material additives 131, for example, a chemical additive. In other embodiments, the slurry is unmodified, for example, an off-the-shelf or other commercially available slurry 17. The material additives 131 can be selected based on their functionality, for example, described in examples below. In other embodiments, other slurry additives can modify the liquid surface tension and the contact angle with the substrate, for example, described in examples below.

At step 904, a lightwave energy source 112 applies electromagnetic wave energy, e.g., light, to the modified slurry 17A. In some embodiments, the lightwave energy source 112 is integral to a slurry processing system, for example, part of the wave energy source 133 of the slurry processing system 10 of FIG. 1 or integral with the container housing 402 of the slurry processing apparatus 400 of FIGS. 4-6. In other embodiments, the lightwave energy source 112 is separate from a slurry processing system, for example, proximal to a substrate 20 on a polishing pad 103 shown in FIG. 1. In some embodiments, the lightwave energy source acts upon a photo-active rate enhancement material additive within the slurry. In some embodiments, additives in addition to or instead of the material additives of step 902 are applied including a photo-active composite vehicle. In some embodiments, the lightwave energy source may operate with a slurry injection system, for example, shown in FIG. 8, and/or described in one or more of U.S. Pat. Nos. 8,197,306, 8,845,395, 9,296,088, Korean Pat. No. 1,394,745, Japan Pat. No. 5,574,597, and Taiwan Pat. No. I486,233, the entireties of each of which is incorporated above.

At step 906, a polishing operation is performed on the slurry modified by both the material additive(s) 131 and the lightwave energy source 112.

The method 910 shown in FIG. 9B includes steps 912 and 914 that are similar to steps 902 and 904 of FIG. 9A and are therefore not repeated due to brevity.

At step 916, the slurry modified by both the material additive(s) 131 and the lightwave energy source 112 is output to a soundwave energy source 113. In some embodiments, the slurry may flow through a mega-sonication process performed by the wave energy source 133. In some embodiments, the soundwave energy source 113 is integral to a slurry processing system, for example, part of the wave energy source 133 of the slurry processing system 10 of FIG. 1 or integral with the container housing 402 of the slurry processing apparatus 400 of FIGS. 4-6. In other embodiments, the soundwave energy source 113 is separate from a slurry processing system, for example, proximal to a wafer 20 on a polishing pad 103 shown in FIG. 1.

At step 918, a polishing operation is performed on the slurry modified by each of the material additive(s) 131, the lightwave energy source 112, and the soundwave energy source 113.

The method 920 shown in FIG. 9C includes steps 922 and 924 that are similar to steps 902 and 904 of FIG. 9A and steps 912 and 914 of FIG. 9B and are therefore not repeated due to brevity. Method step 920 is similar to method 910 of FIG. 9B except that the slurry modified by each of the material additive(s) 131 is first output to the soundwave energy source 113 at step 926, followed by an output to the polishing system 102 at step 928.

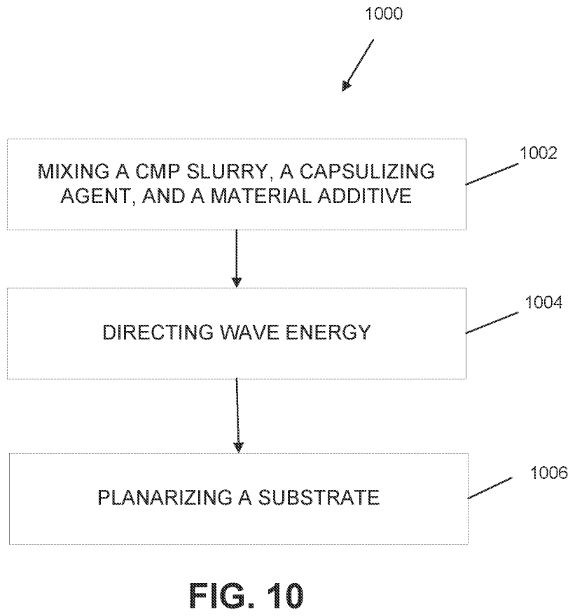

Referring to FIG. 10, a method 1000 is shown. The method 1000 comprises a step 1002 of mixing (1) an aqueous CMP slurry, (2) a capsulizing agent that forms a supramolecular structure and (3) a material additive that generates additional reactive oxygen species (ROS) under the disclosed conditions. Under the reaction conditions, the capsulizing agent forms a supramolecular structure selected from a group consisting of a vesicle, a micelle, a polyelectrolyte and a liposome. Without wishing to be bound to any particular theory the supramolecular structure, upon exposure to mechanical or electromagnetic wave energy, liberates the material additive that then generates additional ROS. The supramolecular structure and material additive effectively function as a macromolecular Fenton additive (MFA) that permits additional or alternative reactive oxygen species to be utilized in method 1000 that normally would be unavailable (or poorly performing). For example, supramolecular structure may permit a material additive with low aqueous solubility to be utilized. Such compounds are liberated when the supramolecular structure is exposed to mechanical or electromagnetic wave energy. In step 1004 wave energy (e.g. mechanical and/or electromagnetic) is directed at the modified slurry, thereby forming an activated modified slurry. The wave energy is believed to break the supramolecular structure and release material additive to form additional reactive oxygen species.

In one embodiment, the wave energy is mechanical wave energy (e.g. sonication) at greater than 0 but less than or equal to 2 Watts per sq. cm. In another embodiment, the sonication occurs at greater than or equal to 0.5 but less than 1.5 Watts per sq. cm. In step 1006, a substrate is planarized while exposed to the activated modified slurry.

Without wishing to be bound to any particular theory, the application of the modified slurry to a substrate is believed to permit the passivation layer atop the substrate surface to be become softer and less dense. This enhances the polishing process in multiple ways. The disclosed methods permit polishing to occur at acceptable material removal rates while using lower applied pressures and/or more gentile conditions. This, in turn, reduces the defects that can occur during polishing. Additionally, higher material removal rates can also be achieved.

The step 1002 of method 1002 may be performed in a variety of ways. In one embodiment, the capsulizing agent and the material additive are individually added to the CMP slurry. Alternatively, the capsulizing agents and the material additive may be pre-mixed in water to form a composition. This composition is then added to the CMP slurry. For example, an aqueous solution that is 10% (m/v) capsulizing agent and 1% (m/v) material additive in water may be formed. In this exemplary composition, the material additive is present in an amount of 10% by weight, relative to the weight of the capsulizing agent.

In some pre-mixing embodiments, the mixed solution is permitted to incubate at room temperature without direct wave agitation for a predetermined period of time. Without wishing to be bound to any particular theory, this incubation is believed to provide time for the capsulizing agent to encapsulate the material additive. For example, pre-mixed solutions prepared using a five-minute incubation time showed a dramatic improvement in material removal rate relative to pre-mixed solutions prepared using a one-minute incubation time (about 4,100 Å per min to about 8,500 Å per min). In one embodiment, the pre-mixed solution is permitted to incubate for a period of greater than two minutes but less than ten minutes. In another embodiment, the pre-mixed solution is permitted to incubate for at least five minutes.

The material additive is generally present in an amount that is between 1.0% (m/m) and 100% (m/m), relative to the weight of the capsulizing agent. In one embodiment, the material additive is present in an amount that is between 1% (m/m) and 50% (m/m), relative to the weight of the capsulizing agent. In another embodiment, the material additive is present in an amount that is between 1% (m/m) and 20% (m/m), relative to the weight of the capsulizing agent. In yet another embodiment, the material additive is present in an amount that is between 5% (m/m) and 15% (m/m), relative to the weight of the capsulizing agent.

A sufficient amount of the capsulizing agent and the material additive are used such that, after mixing with the CMP slurry, the overall solution is between 0.01% (m/v) and 10.0% (m/v) of capsulizing agent and material additive, relative to the overall volume of the solution. In one embodiment, this concentration is between 0.01% (m/v) and 5.0% (m/v), relative to the overall volume of the solution. In another embodiment, this concentration is between 0.05% (m/v) and 2.5% (m/v), relative to the overall volume of the solution. In yet another embodiment, this concentration is between 0.05% (m/v) and 2% (m/v), relative to the overall volume of the solution.

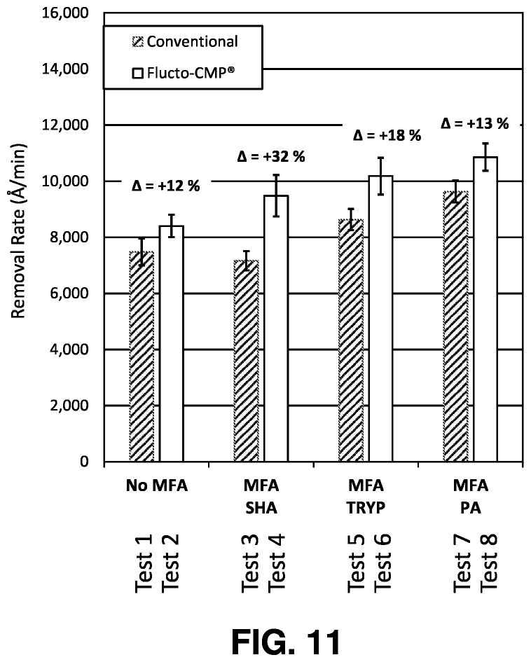

By way of illustration, and not limitation, FIG. 11 depicts several examples of the method 1000. Each of the tests show the performance of a commercial bulk copper slurry mixed with water and hydrogen peroxide (as per the manufacture's specification). In the following tests, all percentages are mass/volume percentages.
Test 1—No capsulizing agent, No material additive, No Sonication, Control: This test was done using a commercial bulk copper slurry (Versum Materials CoppeReady 3930®). Copper metal substrates were polished for 1 minute with a downforce of 3 PSI and a platen speed of 100 RPM. Slurry flow rate was kept at a constant 65 mL/min.
Test 2—No capsulizing agent, No material additive, Sonication, Control: This test was done using a commercial bulk copper slurry (Versum Materials CoppeReady 3930®). Copper metal substrates were polished for 1 minute with a downforce of 3 PSI and a platen speed of 100 RPM. Slurry flow rate was kept at a constant 65 mL/min. The slurry was sonicated at 1.0 Watts per sq. cm in a continuous flow sonicator. Prior to the polish test the modified slurry was incubated for 5 minutes. Sonication produced a +12% enhancement in the material removal rate (A per min) relative to Test 1.
Test 3 and Test 4 utilize the method 1000 with and without sonication. Test 3 and Test 4 specifically utilizes a poloxamer as the capsulizing agent and salicylhydroxamic acid (SHA) as the material additive.
Test 3—Poloxamer as the capsulizing agent, SHA as the material additive, No Sonication: This test was done using a commercial bulk copper slurry (Versum Materials CoppeReady 3930®). The solution was pre-mixed and comprised 10% P-103 (a commercial poloxamer), 1% salicylhydroxamic acid (SHA) and water. The solution was added to the slurry at 0.1%. Copper metal substrates were polished for 1 minute with a downforce of 3 PSI and a platen speed of 100 RPM. Slurry flow rate was kept at a constant 65 mL/min.
Test 4—Poloxamer as the capsulizing agent, SHA as the material additive, Sonication: This test was done using a commercial bulk copper slurry (Versum Materials CoppeReady 3930®). The solution was pre-mixed and comprised 10% P-103 (a commercial poloxamer), 1% salicylhydroxamic acid (SHA) and water. The solution was added to the slurry at 0.1%. Copper metal substrates were polished for 1 minute with a downforce of 3 PSI and a platen speed of 100 RPM. Slurry flow rate was kept at a constant 65 mL/min. The slurry was sonicated at 1.0 Watts per sq. cm in a continuous flow sonicator. Prior to the polish test the slurry was incubated for 5 minutes. Sonication produced a dramatic +32% enhancement in the material removal rate (A per min) relative to Test 3.
Test 5 and Test 6 utilize the method 1000 with and without sonication. Test 5 and Test 6 specifically utilizes a poloxamer as the capsulizing agent and tryptophan (TRYP) as the material additive.
Test 5—Poloxamer as the capsulizing agent, TRYP as the material additive TRYP, No Sonication: This test was done using a commercial bulk copper slurry (Versum Materials CoppeReady 3930®). The solution was pre-mixed and comprised 10% P-103 (a commercial poloxamer), 1% tryptophan and water. The solution was added to the slurry at 0.1%. Copper metal substrates were polished for 1 minute with a downforce of 3 PSI and a platen speed of 100 RPM. Slurry flow rate was kept at a constant 65 mL/min.
Test 6—Poloxamer as the capsulizing agent, TRYP as the material additive, Sonication: This test was done using a commercial bulk copper slurry (Versum Materials CoppeReady 3930®). The solution was pre-mixed and comprised 10% P-103 (a commercial poloxamer), 1% tryptophan and water. The solution was added to the slurry at 0.1%. Copper metal substrates were polished for 1 minute with a downforce of 3 PSI and a platen speed of 100 RPM. Slurry flow rate was kept at a constant 65 mL/min. The slurry was sonicated at 1.0 Watts per sq. cm in a continuous flow sonicator. Prior to the polish test the slurry was incubated for 5 minutes. Sonication produced a +18% enhancement in the material removal rate (Å per min) relative to Test 5.
Test 7 and Test 8 utilize the method 1000 with and without sonication. Test 7 and Test 8 specifically utilizes a poloxamer as the capsulizing agent and phenylalanine (PA) as the material additive.
Test 7—Poloxamer as the capsulizing agent, PA as the material additive, No Sonication: This test was done using a commercial bulk copper slurry (Versum Materials CoppeReady 3930®). The solution was pre-mixed and comprised 10% P-103 (a commercial poloxamer), 1% phenylalanine and water. The solution was added to the slurry at 0.1%. Copper metal substrates were polished for 1 minute with a downforce of 3 PSI and a platen speed of 100 RPM. Slurry flow rate was kept at a constant 65 mL/min.
Test 8—Poloxamer as the capsulizing agent, PA as the material additive, Sonication: This test was done using a commercial bulk copper slurry (Versum Materials CoppeReady 3930®). The solution was pre-mixed and comprised 10% P-103 (a commercial poloxamer), 1% phenylalanine and water. The solution was added to the slurry at 0.1%. Copper metal substrates were polished for 1 minute with a downforce of 3 PSI and a platen speed of 100 RPM. Slurry flow rate was kept at a constant 65 mL/min. The slurry was sonicated at 1.0 Watts per sq. cm in a continuous flow sonicator. Prior to the polish test the slurry was incubated for 5 minutes. Sonication produced a +13% enhancement in the material removal rate (Å per min) relative to Test 7.

TABLE 1

| Entry | Material Removal Rate (Å per min) |
|---|---|
| Test 1 | 7.476 |
| Test 2 | 8.403 |
| Test 3 | 7.163 |
| Test 4 | 9.481 |
| Test 5 | 8.630 |
| Test 6 | 10.180 |
| Test 7 | 9.631 |
| Test 8 | 1.0858 |

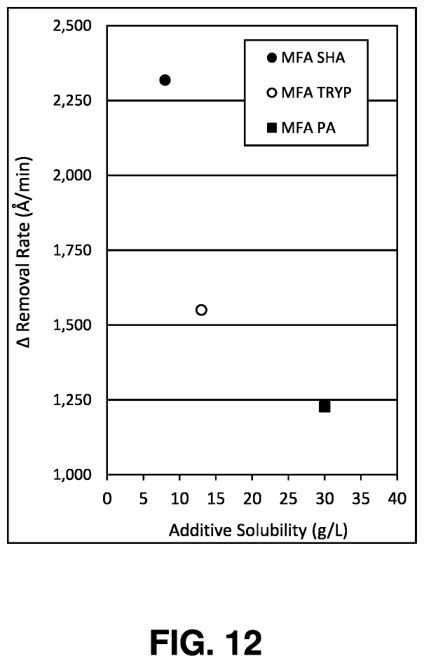

FIG. 12 is a graph of the change in material removal rate due to sonication as a function of additive solubility. Without wishing to be bound to any particular theory, the dramatic +32% enhancement is believed to be due to the low solubility of salicylhydroxamic acid (SHA). The disclosed method permits the use of material additives, such as SHA, with low aqueous solubility. In one embodiment, a material additive is used that has a water solubility of less than 20 grams per liter when measured at 22° C. in deionized water. In another embodiment, a material additive is used that has a water solubility of less than 10 grams per liter when measured at 22° C. in deionized water.

The capsulizing agent forms a supramolecular structure selected from a group consisting of a vesicle, a micelle, a polyelectrolyte and a liposome.

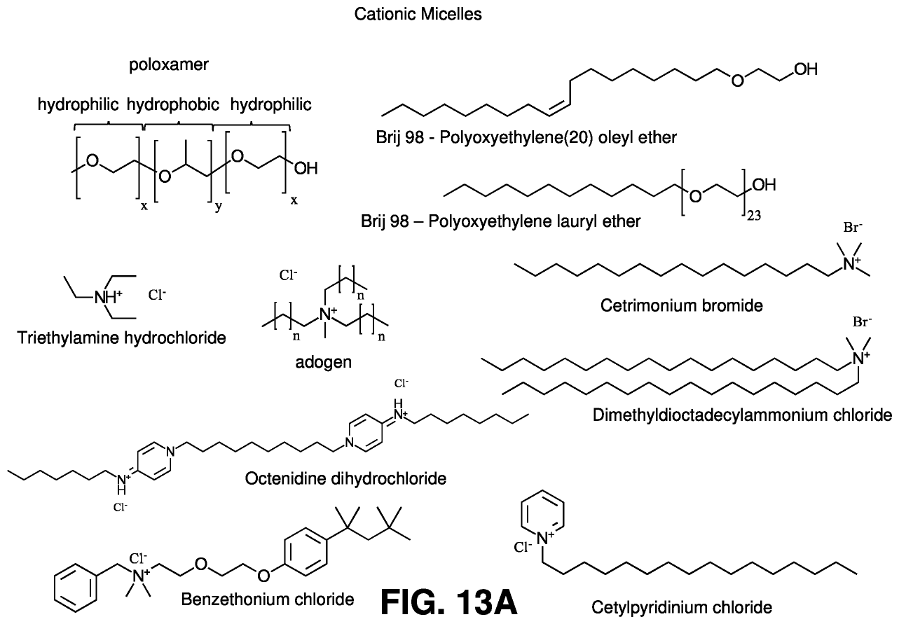

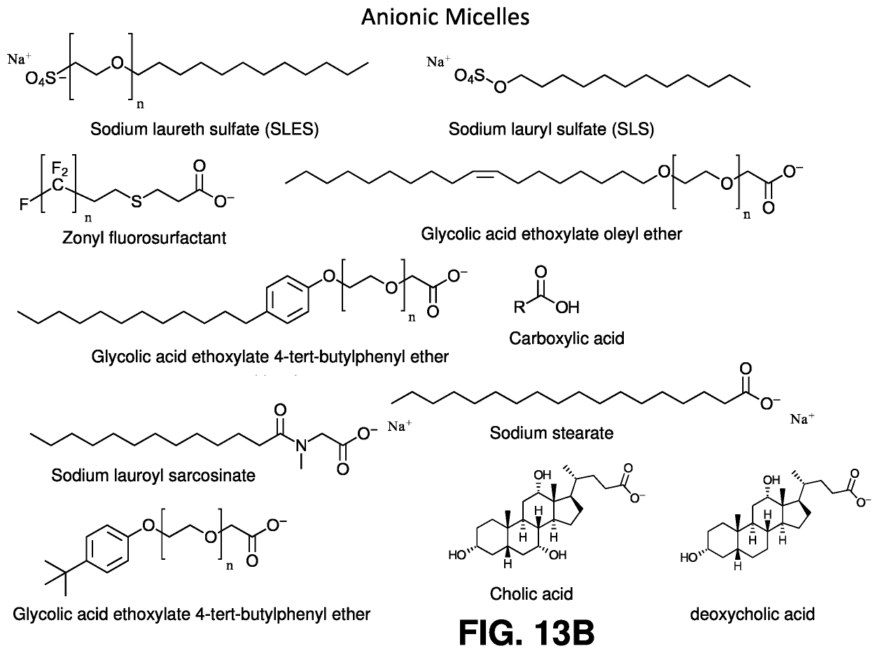

FIG. 13A and FIG. 13B depict examples capsulizing agents that form micelles. A micelle is a single layer aggregate of molecules with both polar and non-polar regions. Poloxamers (the polymerization product of ethylene oxide and propylene oxide) may be used. Numerous poloxamers are known with different molecular weight ranges of the propylene oxide (PO) and weight percentages of ethylene oxide (EO) chains. The molecular weight ranges of the PO chain generally range from 950 Daltons to 4000 Daltons. The weight percent of the EO chains typically range from 10% to 80%. Examples of commercially available poloxamers are shown in Table 2.

TABLE 2

| Molecular weight of | Weight percent of | Commercial |
|---|---|---|
| PO Chain (Daltons) | EO chain (%) | Poloxamer |
| 950 | 10 | L31 |
| 950 | 50 | L35 |
| 950 | 80 | L38 |
| 1200 | 20 | L42 |
| 1200 | 30 | L43 |
| 1200 | 40 | L44 |
| 1750 | 10 | L61 |
| 1750 | 20 | L62 |
| 1750 | 30 | L63 |
| 1750 | 40 | L64 |
| 1750 | 50 | P65 |
| 1750 | 80 | F68 |
| 2050 | 20 | L72 |
| 2050 | 50 | P75 |
| 2050 | 70 | F77 |
| 2250 | 10 | L81 |
| 2250 | 40 | P84 |
| 2250 | 50 | P85 |
| 2250 | 70 | F87 |
| 2250 | 80 | F88 |
| 2750 | 20 | L92 |
| 2750 | 80 | F98 |
| 3250 | 10 | L101 |
| 3250 | 30 | P103 |
| 3250 | 40 | P104 |
| 3250 | 50 | P105 |
| 3250 | 80 | F108 |
| 4000 | 10 | L121 |
| 4000 | 20 | L122 |
| 4000 | 30 | P123 |
| 4000 | 70 | F127 |

Further examples of capsulizing agents that form micelles include cationic micelles and anionic micelles. Cationic micelles include, but are not limited to, organic quaternary ammonium salts. Examples of organic quaternary ammonium salts include hydrogen trialkane ammonium salts (e.g. triethylamine hydrochloride, cetrimonium bromide, benzethonium chloride, dimethyldioctadecylammonium chloride, ANDOGEN(R), cetylpyridinium chloride and octenidine dihydrochloride. Anionic micelles include sulfate ester salts and carboxylic acid salts with at least ten carbons. Examples of sulfate ester salts include sodium laureth sulfate and sodium lauryl sulfate. Examples of carboxylic acid salts include stearate salts, lauroyl sarcosinate salts, glycolic acid ethoxylate 4-ter-butylphenyl ether salts, zonyl fluorosurfactant salts, cholic acid salts, deoxychlolic acid salts, glycolic acid ethoxylate laurylphenyl ether and glycolic acid ethoxylate oleyl ether salts.

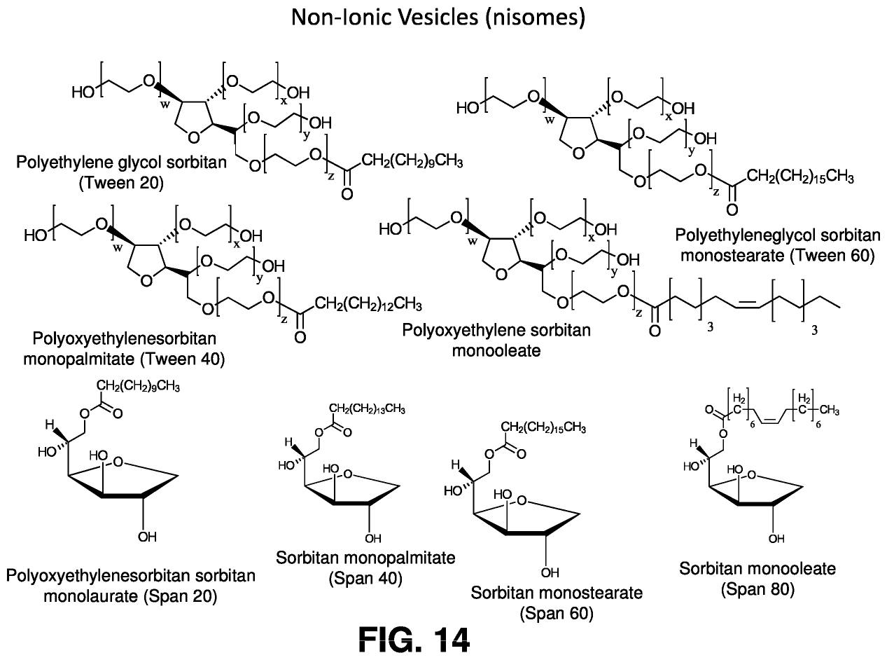

FIG. 14 depicts examples of capsulizing agents that form vesicles. A vesicle is a bilayer aggregate of molecules with both polar and non-polar regions. Examples of vesicles include sorbitan esters such as sorbitan esters and polyethylene glycol sorbitan esters. Example of polyethylene glycol sorbitan esters include polyethylene glycol sorbitan monolaurate (Tween 20), polyoxyethylenesorbitan monopalmitate (Tween 40), polyethylene glycol sorbitan monostearate (Tween 60) and polyoxyethylenesorbitan monooleate (Tween 80). Examples of sorbitan esters include sorbitan monolaurate (Span 20), sorbitan monopalmitate (Span 40), sorbitane monostearate (Span 60) and sorbitan monooleate (Span 80).

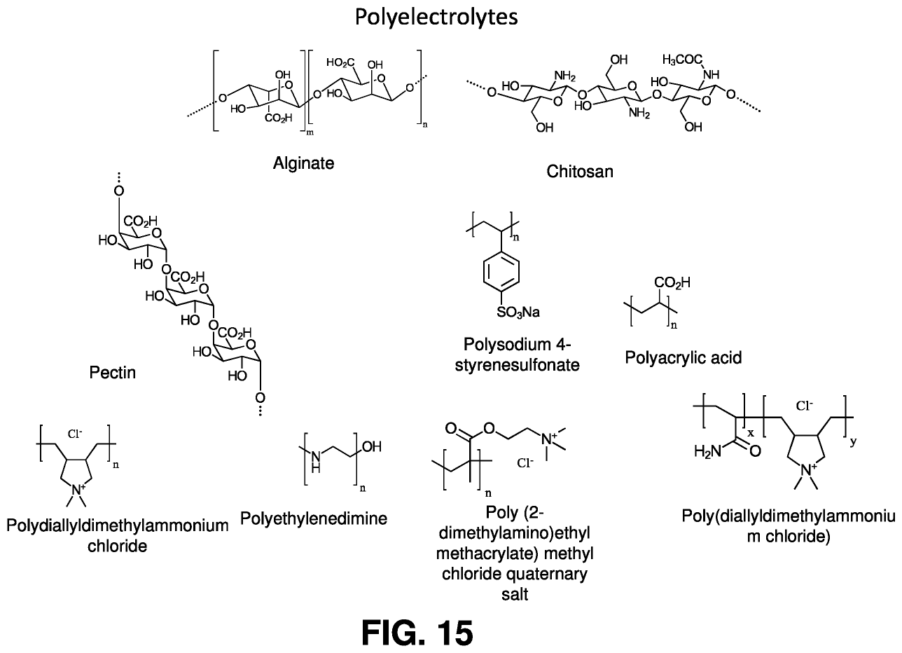

FIG. 15 depicts examples of capsulizing agents that form polyelectrolytes. Polyelectrolytes are macromolecules that, when dissolved in a polar solvent like water, have a (large) number of charged groups covalently linked to them. Based on charge (electrochemistry), polyelectrolytes are divided as polycations(polybase), polyanions(polyacid) and polyampholytes. Polyelectrolytes are grouped into strong and weak polyelectrolytes based on charge density. Strong polyelectrolyte gains spontaneously full charge, while weak polyelectrolyte is only partially charged on dissociation. Examples of polyelectrolytes include alginate, chitosan, pectin, polydiallyldimethylammonium chloride, polyethylenimine, polyacrylic acid, polysodium 4-styrenesulfonate, poly(2-dimethylamino)ethyl methacrylate) methyl chloride quaternary salt, poly(allylamine hydrochloride) and poly(diallyldimethylammonium chloride) solution.

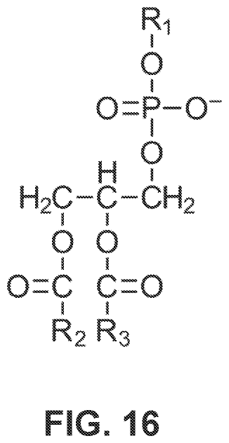

FIG. 16 depicts an example of a capsulizing agent that forms a liposome. Liposome are phospholipids that form micelles or vesicles in aqueous solution. A wide variety of substitution patterns for R₁, R₂ and R₃ are known. For example, R₁ may be H, ethanol amine, choline, serine, glycerol, etc. R₁ and R₂ are linear carbon chains with 8-18 carbons. The carbon chains may be saturated or unsaturated.

Examples of material additives include organic species that form oxygen radicals under the reaction conditions and include ligands (which can complex with metal ions in the commercial CMP slurry and/or complex with the surface of the substrate that is to be planarized), ligand-metal complexes (e.g. pre-formed complexes with metal ions beyond those in the CMP slurry), and non-metal ROS-generating catalysts.

Examples of ligands include salicyhydroxamic acid (SHA), suberohydroxamic acid, tert-butyl N-(benzyloxy)carbamate, bipyridyl, lysine, tryptophan, phenylalanine, tyrosine, ethyl acetohydroxamate, hydroxycarbamide, benzhydroxamic acid, trans-cinnamic acid, adipic acid and caproic acid. In some embodiments, the material additive is a ligand that is pre-mixed to form a ligand-metal complex with a metal ion that is in solution (e.g. a copper ion). Examples of metal ions include magnesium ions, calcium ions, barium ions, nickel ions, copper ions, zinc ions, strontium ions, iron ions, cobalt ions, titanium ions, vanadium ions, chromium ions, molybdenum ions and manganese ions. These metals need not be used in conjunction with a ligand and may be used alone.

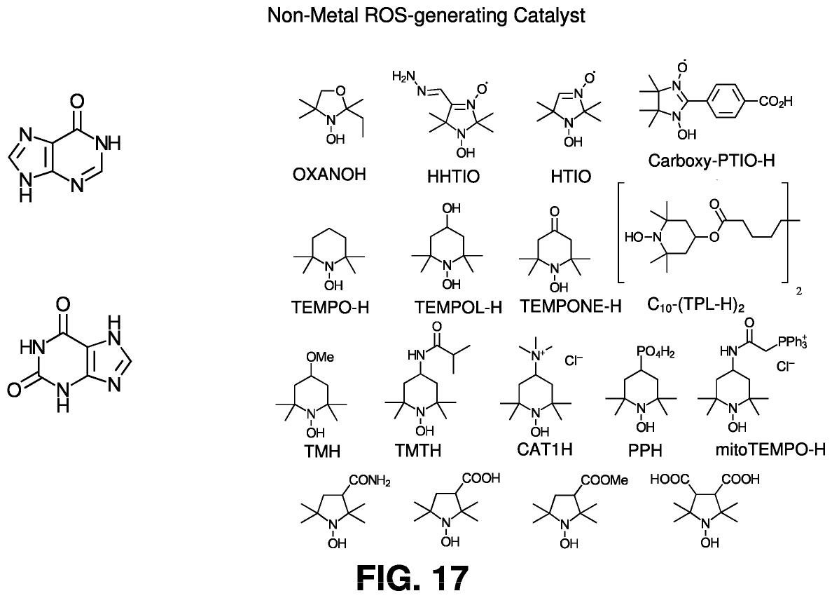

FIG. 17 depicts examples of ROS-generating catalysts that are non-metallic. Such ROS-generating catalysts generate ROS under the reaction conditions (e.g. under photonic or sonic exposure). In one embodiment, the ROS-generating catalyst is an organic (i.e. hydrocarbon containing) catalyst. In one embodiment, the ROS-generating catalyst is an aminooxy radical. (i.e. nitroxyl radical). Examples of compounds that produce aminooxy radicals include OXANOH, HHTIO, HTIO, carboxy-PTIO-H (and its corresponding salts), TEMPO derivatives based on peperidine (e.g. TEMPOH, TEMPOL-H, TEMPONE-H, C₁₀(TPL-H02, TMH, TMTH, CAT1H, PPH, mitoTEMPO-H) and PROXYL derivatives, and the like. In each of these cases, the nitrogen of the nitroxyl radical is flanked by geminal alkyl groups, such as geminal methyl groups. In yet another embodiment, the ROS-generating catalyst is a xanthine or hypoxanthine.

The following are a set of examples that illustrate an operation performed according to a slurry processing technique executed by a CMP slurry processing system described in one or more embodiments herein.

In one example, a wafer polishing apparatus, for example, shown in FIG. 1, has a concentrically grooved pad on which are positioned at least one 300-mm blanket tungsten wafer. The polishing time is configured to be 45 seconds. The slurry includes Versum DP1142-1 with 2% H₂O₂. Another example slurry formulation may include, but not limited to, 1.0 wt % Glycine, 0.5 wt % 60 nm SiO₂ 100 ppm BTA, 1.0wt % H₂O₂ and having a pH=5.8. Another example slurry formulation may include. but not limited to, 1.0 mM Hydroquinone and 1.0 wt % Calcined Ceria, and having a pH of 4.0. Another example slurry formulation may include an inhouse formulation including 1.0 mM Glutamic Acid and 1.0 wt % Calcined Ceria and having a pH of 4.0.

In another example, the slurry injection system 800 shown in FIG. 8 is configured to process slurry at a flow rate of 125 ml/min. The polishing pad 103 rotated at 70 RPM and a sinusoidal sweeping schedule of 10 sweeps per second. A downward force of 7 lbs is applied to the disc. A break-in period of 45 minutes occurs at a pad rotation rate of 80 RPM. An ex-situ conditioning process occurs for 30 seconds. The conventional and inventive dispense systems are configured to apply a polishing pressure of 4 PSI. Sliding velocity is 1.6 meters/second. The power intensity provided at both the conventional slurry dispense system and the slurry processing apparatus 400 is configured to be 20W.

As described above, a CMP slurry processing system 10 can include the lightwave energy source that is part of a polishing operation with respect to a substrate 20 formed of copper, tungsten, silicon carbide, silicon dioxide, or a combination or alloy thereof, and/or other substrate material used for shallow trench isolation (STI) CMP applications requiring the use of a slurry. In some embodiments, the CMP application includes a plasma enhanced tetra-ethoxyorthosilicate (PE-TEOS) SiO₂ CMP process. In some embodiments, the photo-active slurries for STI CMP can be provided by exploiting a ligand-metal charge transfer LMCT mechanism between complex additives and CeO₂ nanoparticles. which in turn can enhance the removal rate during a CMP process. Additives including ligands permit the transfer of electrons from the ligand to the metal surface of the substrate. thus resulting in a reduction of metal ions by the ligand.

In another example, ligand complexing agents such as Tyrosine (Tyr), Phenylalanine (Phe), Tryptophan (Trp), Histidine (HID), and Glycine (Gly) bind with metal ions or the like of the metal oxide surface of the substrate, resulting in the forming of a metal-oxide—ligand complex. Upon irradiation of this complex, for example, by the lightwave energy source 112 of FIGS. 9A-9C, an electron from the coordinated carboxylate group is excited and subsequently transferred into the conduction band (CB) of CeO₂. This in turn reduces Ce⁴⁺ to Ce³⁺ and causes surface O₂ to desorb. Accordingly, the availability of oxygen vacancies for a nucleophilic attack is increased. Additionally, throughout the process, the ligand is oxidized preventing re-adsorption to the nanoparticle which enhances available surface area. Therefore, with an increase in surface activity, i.e., available oxygen vacancies, the oxide removal rate is enhanced during a polishing operation.

In another example, a slurry processing technique may include polymer-based nanocomposite slurries formed by the incorporation of macromolecular polymers such as alginate and pectin, but not limited thereto, with a composite forming additive. Such a material additive offers a dual functionality within the composite, namely, to (1) cross-link the polymer matrix, and (2) integrate itself in the self-cleaning/pressure responsive core. The composite additives can include common rate accelerating additives such as glycine (Gly), L-serine (Ser), itaconic acid (Itac), oxalic acid (Ox), succinic acid (Succ), and hydroquinone (HQ), but not limited thereto. Furthermore, photoactive derivatives of molecules such as azobenzenes, cyclodextrin, Schiff base ligands, spiropyrans, and polyamines can be integrated, either covalent or non-covalently, onto the outer surface of the polymer composites to provide a controlled release of the rate enhancing additives upon irradiation and enhance contaminant removal, i.e., metal ions and/or organometallic complex residues. The covalently linked photoactive functionality derived from the class of molecules can undergo a switchable isomerization upon irradiation from a light generation system or related energy source described in embodiments herein with lighting ultraviolet, visible, or infrared ranges. In addition, upon irradiation with specific wavelengths of light, the material additives have rate-enhancing properties to control a removal rate of the substrate in-situ.

By employing megasonic energy, one can enhance the removal rate of a SiC substrate, in accordance with some embodiments. In such a case, acoustic and light waves, alone or in combination, are applied via a polishing apparatus, for example, shown in FIG. 1, to enhance process performance.

More specifically, in a pre-sonication state, the reactive chemistry resulting in one or more techniques described with respect to embodiments herein can drive film formation kinetics at the SiC substrate resulting in the formation of an abradable layer. Although this layer may be soft, it may also be dense. As such, a significant amount of mechanical energy (that is high values of pressure and sliding velocity) is needed to remove the soft passivation layer and remove surface topography via polishing action. Upon exposure to sonication, there is a shift in the dynamic equilibrium at the substrate surface due to the release of additives as well as the generation of increased critical reactive oxygen species (ROS). These additives will lessen the density of the surface passivation film resulting in an even “softer” and less mechanically reliant interaction. This in turn produces a higher removal rate at low values of working pressure and sliding velocity. These paired systems, i.e., a combination producing slurry formulations and megasonic energy, may result in synergistic improvements that significantly increase material removal rate while minimizing process time, improving defect levels (due to the less mechanical action that is required) and maximizing consumables lifetimes.

The following are a set of example experiments in which one or more of the abovementioned wafers polishing techniques, and comparisons where no sonication or other wave application occurs and where acoustic and/or light waves are applied to a polishing slurry. Here, an internally formulated bulk copper slurry comprising colloidal silica nanoparticles (NPs), water, hydrogen peroxide, copper chelating agent (such as glycine), and copper passivating agent (such as benzotriazole) is used for an experiment. A concentrically grooved pad, for example, Dupont IC1000® pad, is positioned on a 200-mm rotating platen. A 3M (S60-AI) diamond conditioning disc is used in the ex-situ conditioning mode for a duration of 1 minute. Copper metal substrates having a diameter of 25 mm and a thickness of 18 mm are polished. A process pressure ranges between 1 and 5 PSI. A sliding velocity ranges between 0.25 to 1.05 m/s. A slurry flow rate ranges between 25 to 100 cc per minute. An applied sonic energy ranges between 0 and 2.0 Watts per sq. cm. After polishing a total of 90 copper substrates, and depending on process conditions, the observed copper removal rates range from 1,061 to 4.270 Angstroms per minute when sonication energy is set to zero (0) Watts per sq. cm (i.e., no sonication whatsoever). At 1.5 Watts per sq. cm, copper removal rates, based on polishing another 90 wafers, ranges from 1.207 to 6.219 Angstroms per minute. For comparison, at 5 PSI pressure, sliding velocity of 0.65 m/s, and 100 cc per min flow rate processing conditions, tests in which no sonication is employed gave an average copper removal rate of 3,558 Angstroms per minute. Conversely, tests at the 1.5 Watts per sq. cm sonication energy resulted in an average removal rate value of 6,219 Angstroms per minute copper removal rate. This corresponded to an increase of 43 percent in copper removal rate with sonication. In the case of slurry sonication, the incubation time of the slurry in the continuous flow sonicator is zero. That is, the slurry is not kept stagnant, or in any kind of a holding pattern, in the reactor for any period of time. Rather, it is continuously sonicated while flowing through and towards the polisher.

In another example, a Fujimi Corporation PL-7106® commercial copper slurry mixed with water and hydrogen peroxide (as per the manufacture's specification) is used. Employed is a Dupont IC1000® concentrically grooved pad on a 200-mm rotating platen. Furthermore, a 3M (S60-AI) diamond conditioning disc is used in ex-situ conditioning mode for a duration of 1 minute. Copper metal substrates having a diameter of 25 mm and a thickness of 18 mm are polished. An applied process pressure ranges between 1 and 5 PSI. Sliding velocity ranges between 0.25 to 1.05 m/s. Slurry flow rate ranges between 25 to 100 cc per minute. After polishing 90 copper substrates, and depending on process conditions, the observed copper removal rates range from 1,127 to 6,325Angstroms per minute without any sonication. At 1.5 Watts per sq. cm, after polishing another 90 wafers, copper removal rates range from 1,578 to 6,723 Angstroms per minute. For comparison, at 5 PSI pressure, a sliding velocity of 1.05 m/s, and 62.5 cc per min flow rate processing conditions, without any sonication, the results obtained included an average copper removal rate of 6,325 Angstroms per minute while at a sonication energy of 1.5 Watts per sq. cm, an average copper removal rate of 6,723 Angstroms per minute is observed. This corresponded to an increase of 6 percent in copper removal rates with sonication. In the case of slurry sonication, the incubation time of the slurry in the continuous flow sonicator is zero. That is, the slurry is not kept stagnant, or in any kind of a holding pattern, in the reactor for any period of time. Rather, it is continuously sonicated while flowing through and towards the polisher. Further supporting evidence is seen at a 1 PSI and an electrode rotation speed equivalent to 0.25 m/s processing condition. In this case, there is clear evidence for a shift in corrosion with the no sonication case measuring 1.45 micro-amp. While the 1.5 Watt per cm² sonication increased to 18.6 micro-amp.

In another example, a Cabot Microelectronics Corporation SSW7300® commercial tungsten slurry mixed with water and hydrogen peroxide (as per the manufacture's specification) is used. Also employed is a Dupont IC1000® concentrically grooved pad on a 200-mm rotating platen. Furthermore, a 3M (S60-AI) diamond conditioning disc is used in ex-situ conditioning mode for a duration of 1 minute. Tungsten metal substrates having a diameter of 25 mm and a thickness of 18 mm are polished. An applied process pressure ranges between 1 and 5 PSI. A sliding velocity ranges between 0.25 to 1.05 m/s. Slurry flow rate ranges between 25 to 100 cc per minute. Sonic energy ranges between zero and 1.5 Watts per sq. cm. After polishing 90 tungsten substrates. and depending on process conditions, the observed tungsten removal rates range from 1,812 to 2,170 Angstroms per minute when no sonication is used. At 1.5 Watts per sq. cm, after polishing another 90 wafers, tungsten removal rates range from 2,204 to 2,712 Angstroms per minute. For comparison, at 5 PSI pressure, sliding velocity of 1.05 m/s, and 62.5 cc per min flow rate processing conditions, tests without any sonication, an average tungsten removal rate of 2,129 Angstroms per minute. At 1.5 Watts per sq. cm, observed is an average removal rate of 2,712 Angstroms per minute which corresponded to an increase of 27 percent. In the case of slurry sonication, the incubation time of the slurry in the continuous flow sonicator is zero. That is, the slurry is not kept stagnant, or in any kind of a holding pattern, in the reactor for any period of time. Rather, it is continuously sonicated while flowing through and towards the polisher.

In another example, a Versum Materials CoppeReady3930® commercial bulk copper slurry mixed with water and hydrogen peroxide (as per the manufacture's specification) is used. Also employed is a Dupont IC1000® concentrically grooved pad on a 200-mm rotating platen. Also used is a 3M (S60-AI) diamond conditioning disc in the ex-situ conditioning mode for a duration of 1 minute. Copper metal substrates having a diameter of 25 mm and a thickness of 18 mm are polished. A process pressure ranges between 1 and 5 PSI. A sliding velocity ranges between 0.25 to 1.05 m/s. A slurry flow rate ranges between 25 to 100 cc per minute. Sonic energy setpoints are zero and 1.5 Watts per sq. cm. After polishing 90 copper substrates, and depending on process conditions, the observed copper removal rates range from 2,307 to 9,043 Angstroms per minute when sonication energy is turned off. At 1.5 Watts per sq. cm, after polishing another 90 wafers, copper removal rates range from 2,519 to 13,512 Angstroms per minute. For comparison, at 5 PSI pressure and a sliding velocity of 0.65 m/s and 100 cc per min flow rate processing condition, no sonication gave an average copper removal rate of 9.043 Angstroms per minute while at a sonication energy of 1.5 Watts per sq. cm, observed is an average copper removal rate of 13,512 Angstroms per minute. This corresponded to an increase of 49 percent. In the case of slurry sonication, the incubation time of the slurry in the continuous flow sonicator is zero. That is, the slurry is not kept stagnant, or in any kind of a holding pattern, in the reactor for any period of time. Rather, it is continuously sonicated while flowing through and towards the polisher.

In another example, a Versum Materials CoppeReady3930® commercial bulk copper slurry mixed with water and hydrogen peroxide (as per the manufacture's specification) is used. Also employed is a Dupont IC1000® concentrically grooved pad on a 200-mm rotating platen and a 3M (S60-AI) diamond conditioning disc in the ex-situ conditioning mode for a duration of 1 minute. Copper metal substrates having a diameter of 25 mm and a thickness of 18 mm are polished. A process pressure ranges between 1 and 5 PSI. Sliding velocity values are between 0.25 to 1.05 m/s. Slurry flow rates are between 25 to 100 cc per minute. Sonic energy setpoints are at 0.5, 1.5, or 2.0 Watts per sq.cm. After polishing 20 copper substrates, and depending on process conditions, the observed copper removal rates range from 5,563 to 11,504 Angstroms per minute when sonication energy is set to 0.5 Watts per sq. cm. After polishing an additional 20 copper substrates, and depending on process conditions, observed copper removal rates range from 5,789 to 11,377 Angstroms per minute when sonication energy is set to 1.5 Watts per sq. cm. After polishing vet an additional 20 copper substrates, and depending on process conditions, observed copper removal rates range from 2,238 to 7,118 Angstroms per minute when sonication energy is set to 2.0 Watts per sq. cm. Results indicated a 40 percent decrease in average copper removal rate when sonication energy is increased from 0.5 to 2.0 Watts per sq. cm. However, as sonication is further increased to 30 Watts, average copper removal rate dropped by 10 percent from its high at 23 Watts. In the case of slurry sonication, the incubation time of the slurry in the continuous flow sonicator is zero. That is, the slurry is not kept stagnant, or in any kind of a holding pattern, in the reactor for any period of time. Rather, it is continuously sonicated while flowing through and towards the polisher. This indicated that, at least when it came to polishing small substrates, higher sonication energy is not necessarily better for removal rates.

In another example, the Versum Materials CoppeReady3935® commercial high-rate copper slurry mixed with water and hydrogen peroxide (as per the manufacture's specification) is used as well as a Dupont IC1000® concentrically grooved pad on a 200-mm rotating platen and a 3M (S60-AI) diamond conditioning disc in the ex-situ conditioning mode for a duration of 1 minute. Copper metal substrates having a diameter of 25 mm and a thickness of 18 mm are polished. A process pressure ranges between 1 and 5 PSI. A sliding velocity ranges between 0.25 to 1.05 m/s. A slurry flow rate ranges between 25 to 100 cc per minute. Sonic energy setpoints are at 0, 0.5 and 1.5 Watt per sq. cm. After polishing 14 copper substrates, and depending on process conditions, the observed copper removal rates range from 2,069 to 9,512 Angstroms per minute without sonication. After polishing another 14 copper substrates, and depending on process conditions, the observed copper removal rates range from 2,360 to 9,741 Angstroms per minute when sonication energy is set to 0.5 Watts per sq. cm. After polishing yet another 14 copper substrates, and depending on process conditions, observed copper removal rates range from 2,586 to 8,858 Angstroms per minute when sonication energy is set to 1.5 Watts per sq. cm. Results indicated a 10 percent increase in the average copper removal rate when sonication energy is increased from zero to 0.5 Watts per sq. cm. However, as sonication is further increased from 0.5 to 1.5 Watts per sq. cm, the average copper removal rate dropped by 5 percent from its high value at 0.5 Watts per sq. cm. Dynamic electrochemical analysis results performed at the same pressures, slurry flow rates, and velocities as the polishing conditions noted above indicated that the corrosion current ranges from 1.29 to 4.34 micro-amp when sonication energy is set to zero. At a sonication energy of 0.5 Watt per sq.cm, a corrosion current increased such that it ranges from 1.34 to 5.20 micro-amp. However, at a sonication energy of 1.5 Watt per sq.cm, the corrosion current decreased from its high values such that it ranges from 0.56 to 3.22 micro-amp. Trends in corrosion current results are consistent with those of removal rate. In the case of slurry sonication, the incubation time of the slurry in the continuous flow sonicator is zero. That is, the slurry is not kept stagnant, or in any kind of a holding pattern, in the reactor for any period of time. Rather, it is continuously sonicated while flowing through and towards the polisher.

In another example, the Versum Materials Barrier6250® commercial barrier slurry mixed with water and hydrogen peroxide (as per the manufacture's specification) is used. Also employed is the Fujibo H800® embossed pad on a 200-mm rotating platen and a 3M (PB33A-1) bristle brush conditioning disc used in the ex-situ conditioning mode for a duration of 1 minute. Tantalum metal substrates having a diameter of 25 mm and a thickness of 18 mm are polished. Process pressure ranges between 1 and 5 PSI. Sliding velocity ranges between 0.25 to 1.05 m/s. Slurry flow rate is held constant at 62.5 cc per minute. Sonic energy setpoints are at 0, 0.5 or 1.5 Watt per sq. cm. After polishing 14 tantalum substrates, and depending on process conditions, the observed tantalum removal rates range from 250 to 830 Angstroms per minute without sonication. After polishing another 14 tantalum substrates, and depending on process conditions, the observed tantalum removal rates range from 380 to 810 Angstroms per minute when sonication energy is set to 0.5 Watts per sq. cm. After polishing yet another 14 tantalum substrates, and depending on process conditions, the observed tantalum removal rates range from 496 to 1,045 Angstroms per minute when sonication energy is set to 1.5 Watts per sq. cm. Results indicated a 20 percent increase in average tantalum removal rate when sonication energy is increased from zero to 0.5 Watts per sq. cm. As sonication energy is further increased to 1.5 Watts per sq. cm, average tantalum removal rate increased by an additional 10 percent from its value at 0.5 Watts per sq. cm.

In another example, the Versum Materials Barrier6250® commercial barrier slurry mixed with water and hydrogen peroxide (as per the manufacture's specification) is used. Also employed is a Fujibo H800® embossed pad on a 200-mm rotating platen and a 3M (PB33A-1) bristle brush conditioning disc in the ex-situ conditioning mode for a duration of 1 minute. Copper metal substrates having a diameter of 25 mm and a thickness of 18 mm are polished. Process pressure ranges between 1 and 5 PSI. Sliding velocity ranges from 0.25 to 1.05 m/s. Slurry flow rate is kept constant at 62.5 cc per minute. Sonic energy is set at 0. 0.5 or 1.5 Watt per sq. cm. After polishing 14 copper substrates, and depending on process conditions, the observed copper removal rates range from 371 to 635 Angstroms per minute without sonication. After polishing another 14 copper substrates, and depending on process conditions, the observed copper removal rates range from 497 to 1,016Angstroms per minute when sonication energy is set to 0.5 Watts per sq. cm. After polishing yet another 14 copper substrates, and depending on process conditions, the observed copper removal rates range from 583 to 1,219 Angstroms per minute when sonication energy is set to 1.5 Watts per sq. cm. Results indicate a 40 percent increase in average copper removal rate when sonication energy is increased from zero to 0.5 Watts per sq. cm. As sonication is further increased to 1.5 Watts per sq. cm, average copper removal rate increased by an additional 15 percent from its initial average value at 0.5 Watts per sq. cm. At zero Watts per sq. cm the average copper to tantalum removal rate selectivity is 1.04:1. While at 1.5 Watts per sq. cm the average copper to tantalum removal rate selectivity is 1.18:1. In the case of slurry sonication, the incubation time of the slurry in the continuous flow sonicator is zero. That is, the slurry is not kept stagnant, or in any kind of a holding pattern, in the reactor for any period of time. Rather, it is continuously sonicated while flowing through and towards the polisher.

The following examples include the application of a process described above that includes light or sound-activated chemical additives.

In an example, a sono-activated chemical can be added to the off-the-shelf slurry, in particular internally formulated slurry comprised of calcined cerium nanoparticles and redox additives for shallow trench isolation (STI) CMP application is prepared. The material additives are selected based on their functionality. Glutamic acid has carboxylic acid functionality, which is known to suppress oxide removal, while hydroquinone is known to boost oxide removal with hydroxyl functionality. A Dupont IC1000® concentrically grooved pad on a 200-mm rotating platen is used as well as a 3M (S60-AI) diamond conditioning disc in the ex-situ conditioning mode for a duration of 1 minute. 1-inch in diameter silicon wafers which are deposited with tetraethyl orthosilicate (TEOS) based silicon dioxide film are used for polishing. Process pressure ranges from 0.5 and 1.5 PSI. Sliding velocity is kept constant at 0.52 m/s. Slurry flow rate is kept constant at 75 cc per minute. For the no sonication case, TEOS wafer removal rates are observed to range from 3,652 to 6,008 Angstroms per minute with 1.0 millimolar Hydroquinone. For the sonication case at 1.5 Watts per sq. cm, TEOS wafer removal rates are observed to range from 3,124 to 7,587 Angstroms per minute with 1.0 millimolar Hydroquinone. This corresponded to a 10 percent decrease at low sonication but an average increase of 12 percent with an increase in sonication power. For the no sonication case. TEOS wafer removal rates are observed to range from 3,558 to 5,876 Angstroms per minute with 1.0 millimolar Glutamic Acid. For the sonication case at 1.5 Watts per sq. cm, TEOS wafer removal rates are observed to range from 3,611 to 7,831 Angstroms per minute with 1.0 millimolar Glutamic Acid. This corresponded to an average increase of 10 percent. In the case of slurry sonication, the incubation time of the slurry in the continuous flow sonicator is zero. That is, the slurry is not kept stagnant, or in any kind of a holding pattern, in the reactor for any period of time. Rather, it is continuously sonicated while flowing through and towards the polisher.

In another example, an internally formulated slurry for shallow trench isolation (STI) CMP application is prepared by exploiting a Ligand-Metal Charge Transfer (LMCT) mechanism between complexing additives and ceria (colloidal or calcined) nanoparticles (NPs). More specifically, ligands such as Tyrosine (Tyr), Phenylalanine (Phe), Tryptophan (Trp), Histidine (His), and Glycine (Gly) tend to complex with the metal oxide surface via coordination bonds resulting in complexation between the metal-oxide (MOX) and the ligand. Upon irradiation (with wavelengths of light ranging from 250 to 800 nm) of this complex, an electron from the coordinated carboxylate group is excited and ultimately transferred into the conduction band (CB) of the ceria NP. This in turn, reduced Ce⁴⁺ to Ce³⁺ and caused surface O₂ to desorb, thereby increasing the availability of oxygen vacancies for nucleophilic attack. Additionally, throughout this process the ligand is oxidized thus preventing the re-adsorption to the nanoparticle which enhanced the available surface area. Therefore, with an increase in surface activity (i.e., available oxygen vacancies) the oxide removal rate is enhanced significantly. The experimental setup allowed for the slurry to be pumped through a clear acrylic tubing. As such, the slurry could be irradiated either via laser light, or light through a series of LED arrays. For example, the clear pipe sections are acrylic tubing of approximately 2-inch internal diameter (ID) and a length of 18 inches. The tubing is wrapped inside a 16.4-foot LED strips consisting of 300 individual LEDs. The wavelengths of the strips range from 250 to 800 nm. The internally formulated STI slurry is prepared using a calcined ceria NP dispersed in water. Tyrosine is then added to the slurry for effective charge transfer. The Dupont IC1000® concentrically grooved pad on a 200-mm rotating platen is used. Also employed is the 3M (model number) diamond conditioning disc in the ex-situ conditioning mode for a duration of 1 minute. 1-inch in diameter silicon wafers which are deposited with silicon dioxide (using tetraethyl orthosilicate as the precursor) are used for polishing. Process pressure ranges from 1 and 5 PSI. Sliding velocity ranges between 0.25 to 1.05 m/s. Slurry flow rate is kept constant at 75 cc per minute. After polishing silicon dioxide wafers, film removal rates are observed to range from 2,753 to 3,109 Angstroms per minute without irradiation. After polishing another 20 silicon dioxide wafers, film removal rates are observed to range from 2,948 to 3,650 Angstroms per minute with irradiation with the 520 to 525 nanometer green LED. This corresponded to an average increase of 10 percent.

In another example, a Versum Materials CoppeReady3930® commercial bulk copper slurry mixed with water and hydrogen peroxide (as per the manufacture's specification) is used. Also employed are a Dupont IC1000® concentrically grooved pad on a 200-mm rotating platen and a 3M (S60-AI) diamond conditioning disc in the ex-situ conditioning mode for a duration of 1 minute. The copper metal substrates that are used to polish had a diameter of 25 mm and a thickness of 18 mm. Process pressure is at 3 PSI, sliding velocity is at 0.79 m/s, and slurry flow rate is kept constant at 65 cc per minute. Sonic energy is set at 0 or 1.5 Watt per sq. cm. After polishing 10 copper substrates. the observed average copper removal rate is 2,609 Angstroms per minute without any sonication. After polishing another 6 copper substrates, the observed average copper removal rate is 3,623 Angstroms per minute when the slurry is sonicated at 1.5 Watt per sq.cm with no incubation whatsoever. After polishing yet another 7 copper substrates. the observed average copper removal rate is 4,258 Angstroms per minute when the slurry is sonicated at 1.5 Watt per sq.cm, but this time after being incubated for 1 minute. This corresponded to an increase of 39 percent between the no sonication case and the sonication with a 1-minute incubation case.

In another example where a sono-activated chemical is added to an off-the-shelf slurry, an internally formulated silicon carbide CMP slurry comprised of alumina (spherical or oblong) NPs, water, hydrogen peroxide, and an electrophilic enhancer such as organometallic complexes (i.e., Cu⁺²-glycine) or borate derivatives is used. Also employed is a Dupont SUBA800-II-12® X-Y grooved pad on a 200-mm rotating platen and a 3M (PB33A-1) bristle brush conditioning disc in the ex-situ conditioning mode for a duration of 1 minute. Silicon carbide wafers having a diameter of 100 mm and an overall thickness of 500 microns are used for all polishing tests. Process pressure ranges between 1 and 9 PSI. The sliding velocity range is between 0.25 to 1.05 m/s, while the slurry flow rate ranges between 25 to 100 cc per minute. Sonic energy setpoints adopted are between 0 and 2.0 Watts per sq. cm. The silicon face of the silicon carbide substrate is polished using a hydrogen peroxide-based formulation that contained an electrophilic enhancing agent. Depending on process conditions, the observed removal rates range from 1,223 to 1,792 nm per hour when sonication energy is set to zero Watts per sq. cm. At 1.5 Watts per sq. cm, silicon carbide removal rates range from 2,764 to 4,122 nm per hour. These represented an average increase of 58 percent. In the case of slurry sonication, the incubation time of the slurry in the continuous flow sonicator is five minutes. That is, the slurry is not kept stagnant, or in any kind of a holding pattern, in the reactor for any period of time. Rather, it is continuously sonicated while flowing through and towards the polisher. The foregoing includes the addition of a sono-activated chemical to the off-the-shelf slurry.

In another example, the Versum Materials CoppeReady3930® commercial bulk copper slurry mixed with water and hydrogen peroxide (as per the manufacture's specification) is used for polishing. A Dupont IC1000® concentrically grooved pad on a 200-mm rotating platen is employed. Also employed is a 3M (S60-AI) diamond conditioning disc used in the ex-situ conditioning mode for a duration of 1 minute. Copper metal substrates having a diameter of 25 mm and a thickness of 18 mm are used for polishing. Process pressure ranges between 1 and 5 PSI. Sliding velocity between 0.25 to 1.05 m/s. Slurry flow rate ranges from 65 to 120 cc per minute. Sonic energy is kept constant at 1.5 Watt per sq. cm at a 1-minute incubation time. After polishing 10 copper substrates with a slurry flow rate of 65 cc per minute, observed copper removal rates range from 3,433 to 5,132 Angstroms per minute. After polishing 10 copper substrates with a slurry flow rate of 120 cc per minute, observed copper removal rates range from 3,713 to 6,020 Angstroms per minute. In all cases, higher pressures resulted in higher removal rates. Also, higher flow rates caused removal rates to increase by an average of 10 percent.

In another example, the Versum Materials CoppeReady3930® commercial bulk copper slurry mixed with water and hydrogen peroxide (as per the manufacture's specification) is used. Also used is the Dupont IC1000® concentrically grooved pad on a 200-mm rotating platen. A 3M (S60-AI) diamond conditioning disc is further used in the ex-situ conditioning mode for a duration of 1 minute. Copper metal substrates having a diameter of 25 mm and a thickness of 18 mm are polished. The process pressure ranges between 1 and 5 PSI. Sliding velocity ranges between 0.25 to 1.05 m/s. The slurry flow rate is kept constant at 65 cc per minute. Sonication energy settings are 0, 0.5. 1. 1.5, and 2 Watt per sq. cm. In all cases, a 1-minute incubation time is used. After polishing 10 copper substrates, the observed average copper removal rates are around 2,572 Angstroms per minute in the case of no sonication. Removal rates increase to a maximum average value of 4,959 Angstroms per minute at 0.5 Watt per sq. cm and then decrease steadily to 4,455, 3,845 and 3,500 Angstroms per minute as sonication energy increases to 1, 1.5. and 2 Watt per sq. cm, respectively. This indicates the potential for over oxidation (i.e., increase reactive oxygen species) to alter passivation complexation characteristics at the copper surface can be detrimental to removal rate.

In another example, The Versum Materials CoppeReady3930® commercial bulk copper slurry mixed with water and hydrogen peroxide (as per the manufacture's specification) is used. A Dupont IC1000® concentrically grooved pad is employed on a 200-mm rotating platen. A 3M (S60-AI) diamond conditioning disc is used in the ex-situ conditioning mode for a duration of 1 minute. The copper metal substrates used to polish has a diameter of 25 mm. Process pressure is at 3 PSI, sliding velocity is at 0.52 m/s, and slurry flow rate is kept constant at 65 cc per minute. After polishing, the surface of the copper is analyzed using an Atomic Force Microscope. Without sonication, the average value of wafer surface roughness (Ra) is 1.1 nm. When sonic energy is set to 2.0 Watt per sq. cm, the average value of wafer surface roughness (Ra) decreases to 0.78 nm. This represents an improvement of 29 percent in the reduction of surface roughness.

In another example, the Versum Materials DP1236® commercial tungsten slurry mixed hydrogen peroxide (as per the manufacture's specification) is used. A Dupont IC1000® concentrically grooved pad is employed on a 200-mm rotating platen. A 3M (S60-AI) diamond conditioning disc operates in the ex-situ conditioning mode for a duration of 1 minute. The tungsten substrates are polished under a polishing pressure of 3 PSI, sliding velocity of 0.52 m/s, and slurry flow rate of 65 cc per minute. After polishing, the surface of the tungsten substrate is analyzed using an Atomic Force Microscope. Without sonication, the average value of wafer surface roughness (Ra) is 1.07 nm. When sonic energy is set to 2.0 Watt per sq. cm, the average value of wafer surface roughness (Ra) decreases to 0.88 nm. This represents an improvement of 18 percent in reduction of surface roughness.

The following examples include large (200-mm) wafer polishing with and without sonication as described in embodiments above.

In one example, a Versum Materials CoppeReady3930® commercial copper slurry mixed with water and hydrogen peroxide (as per the manufacturer's specification) is used. Furthermore, employed is the Dupont IC1010® concentrically grooved pad on an 800-mm rotating platen. A Saesol 4DNS80AMC1 diamond conditioning disc in the in-situ conditioning mode is used. 200-mm blanket copper wafers are polished for a duration of 30 seconds for each wafer. Process pressure ranges between 1.5 and 2.0 PSI. Sliding velocity is set at 1.5 m/s. Slurry flow rate is held constant at 150 cc per minute. Sonic energy setpoint is at 1 Watt per sq. cm with a 15-minute incubation time. Two polishing runs are conducted for each combination of polishing conditions. At a polishing pressure of 1.5 PSI, the average copper removal rates are at 8,599 and 9,629 Angstroms per minute for the process without sonication, and the one with sonication, respectively. This represented an increase of 12 percent in removal rate. At the polishing pressure at 2.0 PSI, average copper removal rates are at 10,975 and 12,223 Angstroms per minute for the process without sonication, and the one with sonication, respectively. This represents an increase of 11 percent in removal rate.

In another example, the Versum Materials CoppeReady3930® commercial copper slurry mixed with water and hydrogen peroxide (as per the manufacturer's specification) is used. Employed is the Dupont IC1010® concentrically grooved pad on an 800-mm rotating platen as well as a Saesol 4DNS80AMC1 diamond conditioning disc in the in-situ conditioning mode. 200-mm blanket copper wafers are polished for a duration of 30 seconds for each wafer. Process pressure ranges between 1.5 and 2.0 PSI. Sliding velocity is kept constant at 1.5 m/s. Also, the slurry flow rate is held constant at 150 cc per minute. Without sonication, the average copper removal rates are 9,372 and 11,919 Angstroms per minute at polishing pressures of 1.5 and 2.0 PSI, respectively. When the sonic energy setpoint is set at 0.5 Watt per sq. cm with a 15-minute incubation time, the copper removal rate at polishing pressure of 2.0 PSI climbed to 12,260 Angstroms per minute, representing an increase of 3 percent in removal rate. With the sonic energy setpoint at 1.0 Watt per sq. cm, and again with a 15-minute incubation time, the average copper removal rates are at 9,660 and 13,314 Angstroms per minute at polishing pressures of 1.5 and 2.0 PSI, respectively. This represented an increase of 3 and 12 percent in removal rate as compared to the processes without sonication. When the sonic energy is set at 1.5 Watt per sq. cm with a 5-minute incubation time, the copper removal rates are at 9,704 and 13,026 Angstroms per minute at polishing pressures of 1.5 and 2.0 PSI, respectively. This represents an increase of 4 and 9 percent in removal rate as compared to the processes performed without sonication.

In another example, the Versum Materials CoppeReady3930® commercial copper slurry mixed with water and hydrogen peroxide (as per the manufacturer's specification) is used. Also employed is the Dupont IC1010® concentrically grooved pad on an 800-mm rotating platen. Also used is a Saesol 4DNS80AMC1 diamond conditioning disc in the in-situ conditioning mode. 200-mm blanket copper wafers are polished for a duration of 30 seconds for each wafer. Process pressure ranges between 1.5 and 2.0 PSI. Sliding velocity is set at 1.5 m/s. Slurry flow rate is held constant at 150 cc per minute. Without sonication, the average copper removal rates based on a total of 6 wafers polished are 8,403 and 11,006 Angstroms per minute at polishing pressures of 1.5 and 2.0 PSI, respectively. With sonication energy at 1.0 Watt per sq. cm, and with a 5-minute incubation time, copper removal rates based on a total of 4 wafers polished climb to 8,806 and 11,789 Angstroms per minute at polishing pressures of 1.5 and 2.0 PSI, respectively. This represents an increase of 5 and 7 percent in average removal rate as compared to the processes without sonication. When the sonic energy setpoint is at 2.0 Watt per sq. cm and with a 5-minute incubation time, average copper removal rates based on a total of 4 wafers polished also climbed to 9,134 and 12,075 Angstroms per minute at polishing pressures of 1.5 and 2.0 PSI, respectively. This represents an increase of 9 and 10 percent in removal rate as compared to the processes without sonication.

In another example, the Versum Materials CoppeReady3935® commercial copper slurry mixed with water and hydrogen peroxide (as per the manufacturer's specification) is used. Also employed is the Dupont IC1010® concentrically grooved pad on an 800-mm rotating platen. Also used is a Saesol 4DNS80AMC1 diamond conditioning disc in the in-situ conditioning mode. 200-mm blanket copper wafers are polished for a duration of 30 seconds for each wafer. Process pressure ranges between 1.5 and 2.0 PSI. Sliding velocity is set at 1.5 m/s. Slurry flow rate is held constant at 150 cc per minute. Without sonication, the average copper removal rates based on a total of 4 wafers polished are 8,365 and 10,748 Angstroms per minute at polishing pressures of 1.5 and 2.0 PSI, respectively. When the sonic energy is set to 2.0 Watt per sq. cm, ad again with a 5-minute incubation time, the average copper removal rates based on a total of 4 wafers polished climbed to 9,017 and 12,066 Angstroms per minute at polishing pressures of 1.5 and 2.0 PSI, respectively. This represents an increase of 8 and 12 percent in removal rate as compared to the processes without sonication.

In another example, the Versum Materials DP1236® tungsten slurry mixed with hydrogen peroxide (as per the manufacturer's specification) is used. Employed is the Dupont IC1000® XY-grooved pad on an 800-mm rotating platen. Also used is a Saesol 4DNS80AMC1 diamond conditioning disc in the ex-situ conditioning mode for a duration of 30 seconds prior to each wafer polishing. 200-mm blanket tungsten wafers are polished for 60 seconds for each wafer. The process pressure is at 4.0 PSI. Sliding velocity is set at 2.0 m/s. The slurry flow rate is held constant at 125 cc per minute. Without sonication, the average tungsten removal rates based on a total of 6 wafers polished are 2,277 Angstroms per minute. When sonic energy is set to 2.0 Watt per sq. cm, with a 5-minute incubation time, tungsten removal rates based on a total of 6 wafers are 2,423 Angstroms per minute. This represents an increase of 7 percent in removal rate.

In another example, the Versum Materials DP1236® tungsten slurry mixed with hydrogen peroxide (as per the manufacturer's specification) is used. Employed is the Dupont IC1000® XY-grooved pad on an 800-mm rotating platen. Also used is a Saesol 4DNS80AMC1 diamond conditioning disc in the ex-situ conditioning mode for a duration of 30 seconds prior to each wafer polishing. 200-mm blanket tungsten wafers are polished for a duration of 60 seconds for each wafer. The process pressure is at 3.0 PSI. The sliding velocity is set at 1.6 m/s. The slurry flow rate is held constant at 125 cc per minute. Without sonication, the average tungsten removal rates based on a total of 4 wafers polished are 1,646 Angstroms per minute. When sonic energy is set to 2.0 Watt per sq. cm, and again with a 5-minute incubation time, average tungsten removal rates based on a total of 4 wafers polished is 1,803 Angstroms per minute. This represents an increase of 10 percent in removal rate.

In another example, the Versum Materials DP1142® tungsten slurry is mixed with hydrogen peroxide (as per the manufacturer's specification) is used. Employed is the Dupont IC1000® XY-grooved pad on an 800-mm rotating platen. A Saesol 4DNS80AMC1 diamond conditioning disc operates in the ex-situ conditioning mode for a duration of 30 seconds prior to each wafer polishing. One or more 200-mm blanket tungsten wafers are polished for a duration of 45 seconds for each wafer. Process pressure is kept constant at 4.0 PSI. Sliding velocity is also kept constant at 1.6 m/s. Slurry flow rate is held constant at 125 cc per minute. Without sonication, the tungsten removal rate is 1,928 Angstroms per minute. In the case of slurry sonication, slurry is continuously sonicated while flowing through inside a tube passed through the sonicator bowl and towards the polisher. The incubation time of the slurry in the continuous sonicator is estimated to be less than 10 seconds. That is, the slurry is not kept stagnant, or in any kind of a holding pattern, in the reactor for any period of time. When the sonic energy setpoint is at 1.25 Watt per sq. cm, the average tungsten removal rate is 2,112 Angstroms per minute. This represents an increase of 10 percent in removal rate.

In another example, the Versum Materials Cu3930® copper slurry mixed with hydrogen peroxide (as per the manufacturer's specification) is used. Employed is the Dupont IC1000® XY-grooved pad on a 500-mm rotating platen. Also used is a Saesol 4DNS80AMC1 diamond conditioning disc in the ex-situ conditioning mode for a duration of 30 seconds prior to each wafer polishing. 200-mm blanket copper wafers are polished for a duration of 60 seconds for each wafer. Process wafer and retaining ring pressures are kept constant at 1.5 and 1.7 PSI, respectively. Sliding velocity is also kept constant at 0.5 m/s. Slurry flow rate is held constant at 160 cc per minute. Without sonication, the copper removal rate is 4,909 Angstroms per minute. In the case of polishing process with slurry sonication, two sonicator bowls are used in parallel at a slurry flow rate of 80 cc per minute for each bowl, resulting a total slurry flow rate of 160 cc per minute. When the sonic energy of each sonicator bowl is set to 2.0 Watt per sq. cm, and with a 5-minute incubation time, the average copper removal rates increased to 6,221 Angstroms per minute. This represents an increase of 27 percent in removal rate as compared to the processes without sonication.

In another example, the Versum Materials Cu3930® copper slurry mixed with hydrogen peroxide (as per the manufacturer's specification) is used. The Dupont IC1000® XY-grooved pad is employed on a 500-mm rotating platen. Also used is a Saesol 4DNS80AMC1 diamond conditioning disc in the ex-situ conditioning mode for a duration of 30 seconds prior to each wafer polishing. 200-mm blanket copper wafers are polished for a duration of 20 seconds for each wafer. For the first polishing recipe, process wafer and retaining ring pressures are kept constant at 1.5 and 1.7 PSI, respectively and sliding velocity is also kept constant at 0.5 m/s. For the second polishing recipe, process wafer and retaining ring pressures are kept constant at 2.5 and 2.7 PSI, respectively and sliding velocity is also kept constant at 1.6 m/s. Slurry flow rate is held constant at 160 cc per minute on both polishing recipes. Without sonication, the average copper removal rates are 5,703 and 15,552 Angstroms per minute for first and second polishing recipes, respectively. In the case of polishing process with slurry sonication, two sonicator bowls are used in parallel at a slurry flow rate of 80 cc per minute for each bowl, resulting a total slurry flow rate of 160 cc per minute. When the sonic energy of each sonicator bowl is set to 2.0 Watt per sq. cm, and with a 5-minute incubation time, the average copper removal rates increased to 7,397 and 19,383 Angstroms per minute for 1st and 2nd polishing recipes, respectively. This represents an increase of 30 and 25 percent in removal rate as compared to the processes without sonication.

In another example, the Versum Materials DP1236® tungsten slurry mixed with hydrogen peroxide (as per the manufacturer's specification) is used. Employed is the Dupont IC1000® XY-grooved pad on a 500-mm rotating platen. Also used is a Saesol 4DNS80AMC1 diamond conditioning disc in the ex-situ conditioning mode for a duration of 30 seconds prior to each wafer polishing. 200-mm blanket tungsten wafers are polished for a duration of 45 seconds for each wafer. Process wafer and retaining ring pressures are kept constant at 3 and 6 PSI, respectively. Sliding velocity is also kept constant at 1.6 m/s. Slurry flow rate is held constant at 80 cc per minute. Without sonication, the tungsten removal rate is 3,197 Angstroms per minute. In the case of polishing process with slurry sonication, two sonicator bowls are used in parallel at a slurry flow rate of 40 cc per minute for each bowl, resulting a total slurry flow rate of 80 cc per minute. When the sonic energy of each sonicator bowl is set to 2.0 Watt per sq. cm, and with a 5-minute incubation time, the average tungsten removal rates increased to 3,395 Angstroms per minute. This represents an increase of 6 percent in removal rate as compared to the processes without sonication.

While the foregoing has described what is considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A Chemical Mechanical Planarization (CMP) method, the method comprising:
mixing (1) an aqueous CMP slurry (2) a capsulizing agent that forms a supramolecular structure selected from a group consisting of a vesicle, a micelle, a polyelectrolyte and a liposome and (3) a material additive selected from a group consisting of a ligand, a ligand-metal complex and a non-metal reactive-oxygen species (ROS) catalyst, thereby forming a modified slurry;
directing at least one of mechanical or electromagnetic wave energy at the modified slurry, thereby forming an activated modified slurry; and
planarizing a substrate while the substrate is exposed to the activated modified slurry.

2. The method as recited in claim 1, wherein the capsulizing agent is a poloxamer.

3. The method as recited in claim 1, wherein the capsulizing agent is an organic quaternary ammonium salt.

4. The method as recited in claim 1, wherein the capsulizing agent is selected from a group consisting of a hydrogen trialkane ammonium salt and a sulfate ester salt.

5. The method as recited in claim 1, wherein the capsulizing agent is a salt of a carboxylic acid that has at least ten carbons.

6. The method as recited in claim 1, wherein the capsulizing agent is selected from a group consisting of a sorbitan ester and a polyethylene glycol sorbitan ester.

7. The method as recited in claim 1, wherein the capsulizing agent is selected from a group consisting alginate, chitosan, pectin, polydiallyldimethylammonium halide, polyethyleneimine, polyacrylic acid, polysodium 4-styrenesulfonate, poly(2-dimethylamino)ethyl methacrylate) methyl halide quaternary salt, poly(allylamine) hydrohalide, poly(dialyldimethylammonium halide).

8. The method as recited in claim 1, wherein the capsulizing agent is a phospholipid.

9. The method as recited in claim 1, wherein the material additive is a ligand that has a water solubility of less than 20 grams per liter when measured at 22° C.

10. The method as recited in claim 1, wherein the material additive is a ligand that has a water solubility of less than 10 grams per liter when measured at 22° C.

11. The method as recited in claim 1, wherein the material additive is a ligand that is xanthine or hypoxanthine.

12. The method as recited in claim 1, wherein the material additive is a ligand selected from a group consisting of salicyhydroxamic acid (SHA), suberohydroxamic acid, tert-butyl N-(benzyloxy)carbamate, bipyridyl, lysine, tryptophan, phenylalanine, tyrosine, ethyl acetohydroxamate, hydroxycarbamide, benzhydroxamic acid, trans-cinnamic acid, adipic acid and caproic acid.

13. The method as recited in claim 1, wherein the material additive is a ligand that is a hydroxamic acid.

14. The method as recited in claim 1, wherein the material additive is a ligand that is a hydroxamic acid selected from a group consisting of salicyhydroxamic acid (SHA), suberohydroxamic acid, hydroxycarbamide and benzohydroxamic acid.

15. The method as recited in claim 1, wherein the material additive is a ligand that is salicyhydroxamic acid (SHA).

16. The method as recited in claim 1, wherein the material additive is a ligand that is an amino acid.

17. The method as recited in claim 1, wherein the material additive is a ligand that is an amino acid selected from a group consisting of tryptophan and phenylalanine.

18. The method as recited in claim 1, wherein the material additive is a ligand-metal complex with a metal ion selected from a group consisting of a magnesium ion, a calcium ion, a barium ion, a nickel ion, a copper ion, a zinc ion, a strontium ion, an iron ion, a cobalt ion, a titanium ion, a vanadium ion, a chromium ion, a molybdenum ion, and a manganese ion.

19. The method as recited in claim 18, wherein the ligand has a water solubility of less than 20 grams per liter when measured at 22° C.

20. The method as recited in claim 18, wherein the ligand is salicyhydroxamic acid (SHA).

21. The method as recited in claim 1, wherein the step of directing directs mechanical wave energy.

22. A Chemical Mechanical Planarization (CMP) method, the method comprising:
mixing (1) an aqueous CMP slurry (2) a capsulizing agent that forms a supramolecular structure selected from a group consisting of a vesicle, a micelle, a polyelectrolyte and a liposome and (3) a material additive selected from a group consisting of a ligand, a ligand-metal complex and a non-metal reactive-oxygen species (ROS) catalyst, thereby forming a modified slurry, wherein the material additive has a water solubility of less than 20 grams per liter when measured at 22° C.;
directing mechanical wave energy at the modified slurry, thereby forming an activated modified slurry; and
planarizing a substrate while the substrate is exposed to the activated modified slurry.

23. The method as recited in claim 22, wherein the material additive is salicyhydroxamic acid (SHA) and the capsulizing agent is a poloxamer.
